(19) United States
(12) Patent Application Publication
(10) Pub. No.: US 2025/0048879 A1
(43) Pub. Date: Feb. 6, 2025

(54) DISPLAY DEVICE AND METHOD OF MANUFACTURING THE SAME

(71) Applicant: Samsung Display Co., Ltd., Yongin-si (KR)

(72) Inventors: Soo Yeong HONG, Yongin-si (KR); HYANG-A PARK, Yongin-si (KR); GUN HEE KIM, Yongin-si (KR); KWANG SOO BAE, Yongin-si (KR); BOKWANG SONG, Yongin-si (KR)

(21) Appl. No.: 18/664,143

(22) Filed: May 14, 2024

(30) Foreign Application Priority Data
Aug. 2, 2023 (KR) 10-2023-0100983

(51) Int. Cl. H10K 59/65; G06V 40/13; H10K 59/12; H10K 59/38; H10K 59/40; H10K 59/80

(52) U.S. Cl. CPC H10K 59/65; G06V 40/1318; H10K 59/1201; H10K 59/38; H10K 59/40; H10K 59/8792

(57) ABSTRACT

Provided is a display device including a base layer, a circuit layer above the base layer, and an element layer above the circuit layer, and including a light-emitting element including a first pixel electrode electrically connected to the circuit layer, a light-emitting layer above the first pixel electrode, and a second pixel electrode above the light-emitting layer, and a light-receiving element adjacent to the light-emitting element, and including a first sensing electrode electrically connected to the circuit layer, a photoelectric conversion layer above the first sensing electrode, and a second sensing electrode above the photoelectric conversion layer and having a thickness that is different than a thickness of the second pixel electrode.

### CROSS-REFERENCE TO RELATED APPLICATION

The present application claims priority to and the benefit of Korean Patent Application No. 10-2023-0100983, filed on Aug. 2, 2023, in the Korean Intellectual Property Office, the entire disclosure of which is incorporated herein by reference.

### BACKGROUND

### 1. Field

The present disclosure herein relates to a reliable display device and a method of manufacturing the same.

### 2. Description of the Related Art

Various display devices used in multimedia devices, such as televisions, mobile phones, tablet computers, navigation systems, and game consoles, are being developed, and the fields of use of the display devices are diversified. Therefore, the types of display panels for displaying images on the display devices are also diversified. The display panels include a light-emitting display panel, and the light-emitting display panel may include an organic light-emitting display panel, an inorganic light-emitting display panel, a quantum dot light-emitting display panel, or the like.

The display devices provide various functions to make it possible to organically communicate with a user, such as providing information to the user by displaying images or sensing the inputs of the user. Recent display devices include a function for sensing the biometric information of a user.

### SUMMARY

The present disclosure provides a display device and a method of manufacturing the display device that may improve not only the sensing accuracy of biometric information, but also display quality.

A display device according to one or more embodiments of the present disclosure may include a base layer, a circuit layer above the base layer, and an element layer above the circuit layer, and may include a light-emitting element including a first pixel electrode electrically connected to the circuit layer, a light-emitting layer above the first pixel electrode, and a second pixel electrode above the light-emitting layer, and a light-receiving element adjacent to the light-emitting element, and may include a first sensing electrode electrically connected to the circuit layer, a photoelectric conversion layer above the first sensing electrode, and a second sensing electrode above the photoelectric conversion layer and having a thickness that is different than a thickness of the second pixel electrode.

The thickness of the second sensing electrode may be greater than the thickness of the second pixel electrode.

The second pixel electrode may include a pixel electrode layer, and the second sensing electrode may include a first sensing electrode layer extending from the pixel electrode layer, and a second sensing electrode layer above the first sensing electrode layer.

The second pixel electrode may include a pixel electrode layer, and the second sensing electrode may include a first sensing electrode layer, and a second sensing electrode layer above first sensing electrode layer and extending from the pixel electrode layer.

The element layer may define a light-emitting region overlapping the light-emitting layer, and a non-light-emitting region surrounding the light-emitting region in a plan view.

The second pixel electrode may include a first pixel electrode portion corresponding to the light-emitting region, and a second pixel electrode portion corresponding to the non-light-emitting region.

A thickness of the first pixel electrode portion may be different from a thickness of the second pixel electrode portion.

The thickness of the second pixel electrode portion may be greater than the thickness of the first pixel electrode portion.

The thickness of the second pixel electrode portion may be substantially equal to the thickness of the second sensing electrode.

The element layer may define a sensing region overlapping the photoelectric conversion layer and a non-sensing region surrounding the sensing region.

The second sensing electrode may include a first sensing electrode portion corresponding to the sensing region, and a second sensing electrode portion corresponding to the non-sensing region.

A thickness of the first sensing electrode portion may be different from a thickness of the second sensing electrode portion.

The thickness of the first sensing electrode portion may be greater than the thickness of the second sensing electrode portion.

The thickness of the second sensing electrode portion may be substantially equal to the thickness of the second pixel electrode.

The second pixel electrode and the second sensing electrode may be electrically connected to each other.

The circuit layer may include a pixel-driving circuit electrically connected to the light-emitting element for controlling an operation of the light-emitting element, and a sensing-driving circuit electrically connected to the light-receiving element for controlling the operation of the light-receiving element.

The display device may further include a black matrix above the element layer, and including openings, and a color filter above the element layer, and overlapping the openings.

A method of manufacturing a display device according to one or more embodiments may include placing a circuit layer above a base layer, and placing an element layer including a light-emitting element and a light-receiving element above the circuit layer, the placing of the element layer including forming a first pixel electrode of the light-emitting element and a first sensing electrode of the light-receiving element above the circuit layer, forming a light-emitting layer on the first pixel electrode and a photoelectric conversion layer above the first sensing electrode, and forming a second pixel electrode above the light-emitting layer and a second sensing electrode on the photoelectric conversion layer, a thickness of the second sensing electrode being greater than a thickness of the second pixel electrode.

The forming of the second pixel electrode and the second sensing electrode may include forming a first pixel electrode layer above the light-emitting layer, and a first sensing electrode layer above the photoelectric conversion layer, and forming a second sensing electrode layer above the first sensing electrode layer.

The first pixel electrode layer and the first sensing electrode layer may be integrally formed with each other.

### BRIEF DESCRIPTION OF DRAWINGS

The accompanying drawings are included to provide a further understanding of the present disclosure, and are incorporated in and constitute a part of this specification. The drawings illustrate embodiments of the present disclosure and, together with the description, serve to explain the aspects of the present disclosure. In the drawings:

FIG. 1 is a perspective view of a display device according to one or more embodiments of the present disclosure;

FIG. 2 is a cross-sectional view of the display device according to one or more embodiments of the present disclosure;

FIG. 3 is a block diagram of the display device according to one or more embodiments of the present disclosure;

FIG. 4A is an enlarged plan view of a partial region of a display panel according to embodiments of the present disclosure;

FIG. 4B is an enlarged plan view of a partial region of the display panel according to embodiments of the present disclosure;

FIG. 5 is a circuit diagram illustrating a pixel and a sensor of the display panel according to one or more embodiments of the present disclosure;

FIG. 6 is a cross-sectional view illustrating a pixel and a sensor of the display device according to one or more embodiments of the present disclosure;

FIG. 7A is an enlarged cross-sectional view of a display panel according to one or more embodiments of the present disclosure;

FIG. 7B is an enlarged cross-sectional view of a display panel according to one or more embodiments of the present disclosure;

FIG. 7C is an enlarged cross-sectional view of a display panel according to one or more embodiments of the present disclosure; and

FIGS. 8A to 8G are cross-sectional views for describing a step of forming a portion of the display device according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

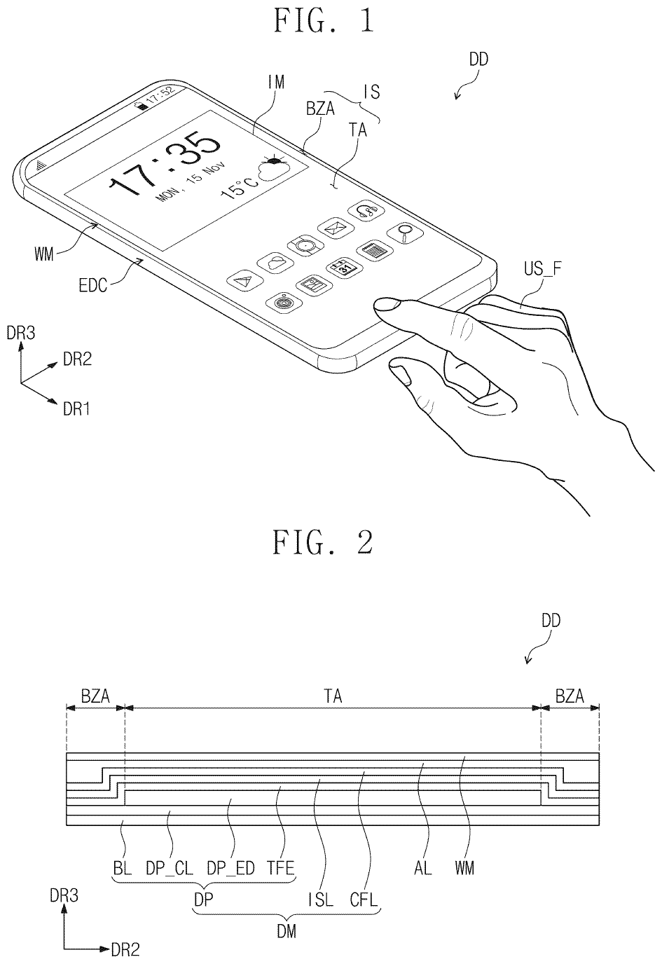

FIG. 1 is a perspective view of a display device according to one or more embodiments of the present disclosure. FIG. 2 is a cross-sectional view of the display device according to one or more embodiments of the present disclosure.

Referring to FIGS. 1 and 2, the display device DD according to one or more embodiments of the present disclosure may have a rectangular shape with long sides parallel to a first direction DR1, and with short sides parallel to a second direction DR2 crossing the first direction DR1. Without being limited thereto, however, the display device DD may have various shapes, such as a circle and a polygon.

The display device DD may be activated according to an electrical signal. The display device DD may include various embodiments. For example, the display device DD may be applied to electronic devices, such as a smart watch, a tablet, a laptop computer, a computer, and a smart television.

Hereinafter, a normal direction substantially perpendicular to a plane defined by the first direction DR1 and the second direction DR2 is defined as a third direction DR3. In this specification, the expression “when viewed on a plane” may mean a state viewed from the third direction DR3.

The upper surface of the display device DD may be defined as a display surface IS, and may be parallel to a plane defined by the first direction DR1 and the second direction DR2. Images IM generated in the display device DD may be provided to a user through the display surface IS.

The display surface IS may be divided into a transmission region TA and a bezel region BZA. The transmission region TA may be a region in which images IM are displayed. A user views the images IM through the transmission region TA. In one or more embodiments, the transmission region TA is illustrated as a tetragonal shape with rounded vertices. However, this is illustrated as an example and the transmission region TA may have various shapes, and the present disclosure is not limited to any one embodiment.

The bezel region BZA may be adjacent to the transmission region TA. The bezel region BZA may have a color (e.g., preset color). The bezel region BZA may surround the transmission region TA. Accordingly, the shape of the transmission region TA may be substantially defined by the bezel region BA. However, this is illustrated as an example, and the bezel region BZA may be located adjacent to only one side of the transmission region TA or may be omitted.

The display device DD can sense an external input applied from the outside. The external input may include various types of inputs provided from the outside of the display device DD. For example, the external input may include a contact by a part of a user's body, such as a hand US_F of the user or a contact by a separate device (e.g., an active pen or digitizer, etc.), and also may include an external input (for example, hovering) applied in proximity to the display device DD or adjacent to the display device DD at a distance (e.g., preset distance). In addition, the external input may have various forms, such as force, pressure, temperature, and light.

The display device DD may sense the biometric information of a user, which may be applied from the outside. A biometric information sensing region capable of sensing the user's biometric information may be provided to the display surface IS of the display device DD. The biometric information sensing region may be provided to the entire region of the transmission region TA, or to a partial region thereof. FIG. 1 illustrates that the entire transmission region TA may be used as a biometric information sensing region according to one or more embodiments of the present disclosure.

The display device DD may include a window WM, a display module DM, and a housing EDC. In one or more embodiments, the window WM and the housing EDC are coupled to each other to form the exterior of the display device DD.

The front surface of the window WM defines the display surface IS of the display device DD. The window WM may contain an optically transparent insulating material. For example, the window WM may contain glass or plastic. The window WM may have a multi-layered structure or a single-layered structure. For example, the window WM may include a plurality of plastic films bonded to each other with an adhesive or may include a glass substrate and a plastic film bonded to each other with an adhesive.

The display module DM may include a display panel DP and an input-sensing layer ISL. The display panel DP may display an image according to an electrical signal, and the input-sensing layer ISL may sense an external input applied from the outside. The external input may be provided in various forms.

The display panel DP according to one or more embodiments of the present disclosure may be a light-emitting display panel, but the present disclosure is not limited thereto. For example, the display panel DP may be an organic light-emitting display panel, an inorganic light-emitting display panel, or a quantum dot light-emitting display panel. A light-emitting layer of the organic light-emitting display panel may contain an organic light-emitting material. A light-emitting layer of the inorganic light-emitting display panel may contain an inorganic light-emitting material. A light-emitting layer of the quantum dot light-emitting display panel may contain quantum dots and quantum rods. Hereinafter, the display panel DP will be described as an organic light-emitting display panel.

Referring to FIG. 2, the display panel DP may include a base layer BL, a circuit layer DP_CL, an element layer DP_ED, and an encapsulation layer TFE. The display panel DP according to one or more embodiments of the present disclosure may be a flexible display panel. However, the present disclosure is not limited thereto. For example, the display panel DP may be a rigid display panel or a foldable display panel that may be folded around a folding axis.

The base layer BL may include a synthetic resin layer. The synthetic resin layer may contain a polyimide-based resin, but its material is not limited thereto. In addition, the base layer BL may include a glass substrate, a metal substrate, or an organic/inorganic composite material substrate.

The circuit layer DP_CL may be located on the base layer BL. The circuit layer DP_CL may be located between the base layer BL and the element layer DP_ED. The circuit layer DP_CL may include at least one insulating layer and a circuit element. Hereinafter, the insulating layer included in the circuit layer DP_CL is referred to as an intermediate insulating layer. The intermediate insulating layer may include at least one intermediate inorganic film and at least one intermediate organic film. The circuit element may include a pixel-driving circuit included in each of a plurality of pixels for displaying an image and a sensor-driving circuit included in each of a plurality of sensors for recognizing external information. The external information may be biometric information. According to one or more embodiments of the present disclosure, the sensor may be a fingerprint recognition sensor, a proximity sensor, an iris recognition sensor, a blood pressure measurement sensor, an illumination sensor, or the like. In addition, the sensor may be an optical sensor that recognizes biometric information in an optical method. The circuit layer DP_CL may further include signal lines connected to the pixel-driving circuit and/or the sensor-driving circuit.

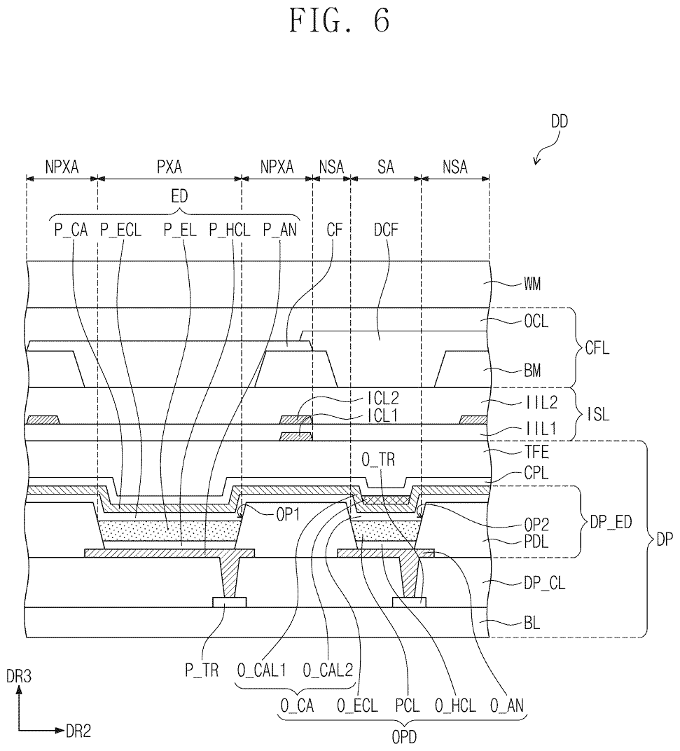

The element layer DP_ED may include a light-emitting element included in each pixel and a light-receiving element included in each sensor. According to one or more embodiments of the present disclosure, the light-receiving element may be a photodiode. The light-receiving element may be a sensor that senses or reacts to light reflected from a user's fingerprint. The circuit layer DP_CL and the element layer DP_ED will be described in detail later with reference to FIG. 6.

The encapsulation layer TFE seals the element layer DP_ED. The encapsulation layer TFE may include at least one organic film and at least one inorganic film. The inorganic film contains an inorganic material and may protect the element layer DP_ED from moisture/oxygen. The inorganic film may include a silicon nitride layer, a silicon oxynitride layer, a silicon oxide layer, a titanium oxide layer, an aluminum oxide layer, or the like. The organic film contains an organic material and may protect the element layer DP_ED from foreign substances, such as dust particles.

The input-sensing layer ISL may be formed on the display panel DP. The input-sensing layer ISL may be directly located on the encapsulation layer TFE. According to one or more embodiments of the present disclosure, the input-sensing layer ISL may be formed on the display panel DP through a continuous process. For example, when the input-sensing layer ISL is directly located on the display panel DP, an adhesive film may not be located between the input-sensing layer ISL and the encapsulation layer TFE. Alternatively, an adhesive film may be located between the input-sensing layer ISL and the display panel DP. In this case, the input-sensing layer ISL is not manufactured through a continuous process with the display panel DP, but the input-sensing layer ISL may be manufactured through a process separate from that of the display panel DP and then bonded to the upper surface of the display panel DP with an adhesive film.

The input-sensing layer ISL may sense an external input (for example, a user's touch), change the external input into a preset input signal, and may provide the input signal to the display panel DP. The input-sensing layer ISL may include a plurality of sensing electrodes for sensing an external input. The sensing electrodes may sense the external input in a capacitive manner. The display panel DP may receive an input signal from the input-sensing layer ISL and generate an image corresponding to the input signal.

The display module DM may further include a color filter layer CFL. According to one or more embodiments of the present disclosure, the color filter layer CFL may be located on the input-sensing layer ISL. However, the present disclosure is not limited thereto. The color filter layer CFL may be located between the display panel DP and the input-sensing layer ISL. The color filter layer CFL may include a plurality of color filters and a black matrix.

Details on the structures of the input-sensing layer ISL and color filter layer CFL will be described later.

The display device DD according to one or more embodiments of the present disclosure may further include an adhesive layer AL. The window WM may be attached to the input-sensing layer ISL by the adhesive layer AL. The adhesive layer AL may contain an optically clear adhesive, an optically clear adhesive resin, or a pressure sensitive adhesive (PSA).

The housing EDC may be coupled to the window WM. The housing EDC may be coupled to the window WM to provide a preset internal space. The display module DM may be accommodated in the internal space. The housing EDC may contain a material with relatively high rigidity. For example, the housing EDC may include a plurality of frames and/or plates made of glass, plastic, metal, or a combination thereof. The housing EDC may stably protect the components of the display device DD accommodated in the internal space from an external impact. In one or more embodiments, a battery module, which supplies power required for the overall operation of the display device DD, may be located between the display module DM and the housing EDC.

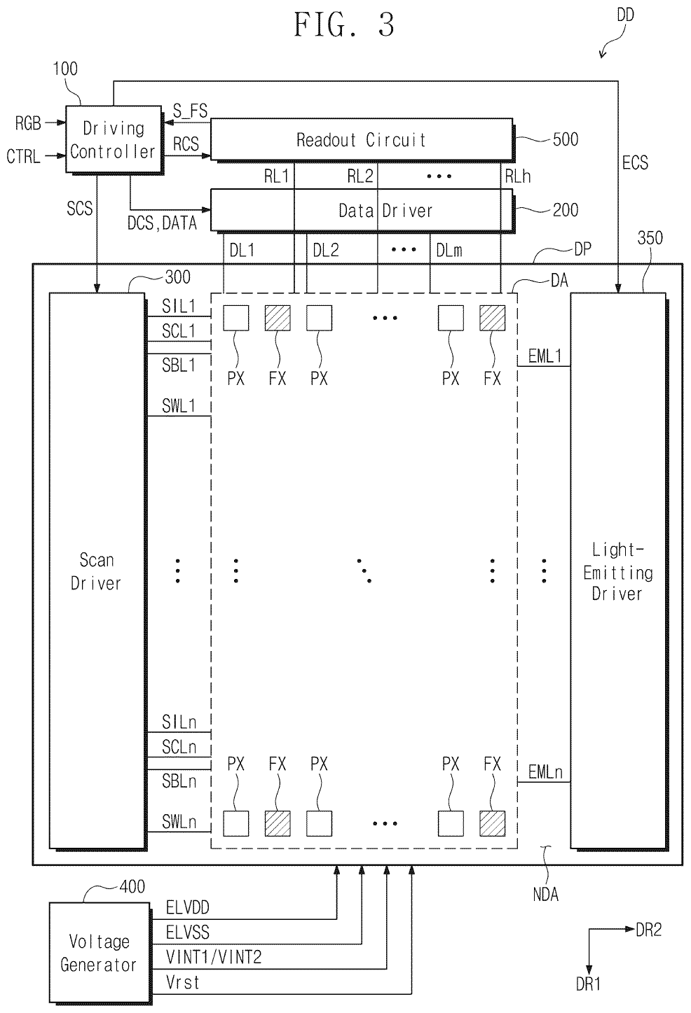

FIG. 3 is a block diagram of the display device according to one or more embodiments of the present disclosure.

Referring to FIG. 3, the display device DD may include a display panel DP, a panel driver, and a driving controller 100. According to one or more embodiments of the present disclosure, the panel driver may include a data driver 200, a scan driver 300, a light-emitting driver 350, a voltage generator 400, and a readout circuit 500.

The driving controller 100 may receive an image signal RGB and a control signal CTRL. The driving controller 100 may generate an image data signal DATA obtained by converting a data format of the image signal RGB so as to meet the interface specifications with the data driver 200. The driving controller 100 may output a first control signal SCS, a second control signal ECS, a third control signal DCS, and a fourth control signal RCS.

The data driver 200 may receive the third control signal DCS and the image data signal DATA from the driving controller 100. The data driver 200 may convert the image data signal DATA into data signals, and may output the data signals to a plurality of data lines DL1 to DLm, which will be described later. The data signals may be analog voltages corresponding to the grayscale values of the image data signal DATA.

The scan driver 300 may receive the first control signal SCS from the driving controller 100. The scan driver 300 may output scan signals through scan lines in response to the first control signal SCS.

The voltage generator 400 may generate voltages suitable for the operation of the display panel DP. In one or more embodiments, the voltage generator 400 may generate a first driving voltage ELVDD, a second driving voltage ELVSS, a first initialization voltage VINT1, and a second initialization voltage VINT2.

The display panel DP may include a display region DA corresponding to the transmission region TA (illustrated in FIG. 1) and a non-display region NDA corresponding to the bezel region BZA (illustrated in FIG. 1).

The display panel DP may include a plurality of pixels PX located in the display region DA and a plurality of sensors FX located in the display region DA. According to one or more embodiments of the present disclosure, each of the plurality of sensors FX may be located between two adjacent pixels PX. The plurality of pixels PX and the plurality of sensors FX may be alternately arranged in the first and second directions DR1 and DR2. However, the present disclosure is not limited thereto. For example, two or more pixels PX may be located between two adjacent sensors FX in the first direction DR1 among the plurality of sensors FX, or two or more pixels PX may be located between two adjacent sensors FX in the second direction DR2 among the plurality of sensors FX.

The display panel DP may include initialization scan lines SIL1 to SILn, compensation scan lines SCL1 to SCLn, write scan lines SWL1 to SWLn, black scan lines SBL1 to SBLn, light-emitting control lines EML1 to EMLn, data lines DL1 to DLm, and readout lines RL1 to RLh. The initialization scan lines SIL1 to SILn, the compensation scan lines SCL1 to SCLn, the write scan lines SWL1 to SWLn, the black scan lines SBL1 to SBLn, and the light-emitting control lines EML1 to EMLn extend in the second direction DR2. The initialization scan lines SIL1 to SILn, the compensation scan lines SCL1 to SCLn, the write scan lines SWL1 to SWLn, the black scan lines SBL1 to SBLn, and the light-emitting control lines EML1 to EMLn are arranged to be spaced apart from each other in the first direction DR1. The data lines DL1 to DLm and the readout lines RL1 to RLh extend in the first direction DR1 and are arranged to be spaced apart from each other in the second direction DR2.

The plurality of pixels PX may be respectively electrically connected to the initialization scan lines SIL1 to SILn, the compensation scan lines SCL1 to SCLn, the write scan lines SWL1 to SWLn, the black scan lines SBL1 to SBLn, the light-emitting control lines EML1 to EMLn, and the data lines DL1 to DLm. For example, each of the plurality of pixels PX may be electrically connected to four scan lines. However, the number of the scan lines connected to each pixel PX is not limited thereto and may be changed.

The plurality of sensors FX may be respectively electrically connected to the write scan lines SWL1 to SWLn and the readout lines RL1 to RLh. Each of the plurality of sensors FX may be electrically connected to one scan line. However, the present disclosure is not limited thereto. The number of the scan lines connected to each sensor FX may be variable. According to one or more embodiments of the present disclosure, the number of the readout lines RL1 to RLh may be less than or equal to the number of the data lines DL1 to DLm. For example, the number of the readout lines RL1 to RLh may correspond to ½, ¼, or ⅛ of the number of the data lines DL1 to DLm.

The scan driver 300 may be located in the non-display region NDA of the display panel DP. The scan driver 300 may receive the first control signal SCS from the driving controller 100. The scan driver 300 may output initialization scan signals to the initialization scan lines SIL1 to SILn and compensation scan signals to the compensation scan lines SCL1 to SCLn in response to the first control signal SCS. In addition, the scan driver 300 may output write scan signals to the write scan lines SWL1 to SWLn and black scan signals to the black scan lines SBL1 to SBLn in response to the first control signal SCS. Alternatively, the scan driver 300 may include first and second scan drivers. The first scan driver may output initialization scan signals and compensation scan signals, and the second scan driver may output write scan signals and black scan signals.

The light-emitting driver 350 may be located in the non-display region NDA of the display panel DP. The light-emitting driver 350 may receive the second control signal ECS from the driving controller 100. The light-emitting driver 350 may output light-emitting control signals to the light-emitting control lines EML1 to EMLn in response to the second control signal ECS. Alternatively, the scan driver 300 may be connected to the light-emitting control lines EML1 to EMLn. In this case, the light-emitting driver 350 may be omitted, and the scan driver 300 may output light-emitting control signals to the light-emitting control lines EML1 to EMLn.

The readout circuit 500 may receive the fourth control signal RCS from the driving controller 100. The readout circuit 500 may receive readout signals from the readout lines RL1 to RLh in response to the fourth control signal RCS. The readout circuit 500 may process the readout signals received from the readout lines RL1 to RLh, generate sensing signals S_FS, and may provide the generated sensing signals S_FS to the driving controller 100. Based on the sensing signals S_FS, the driving controller 100 may recognize biometric information.

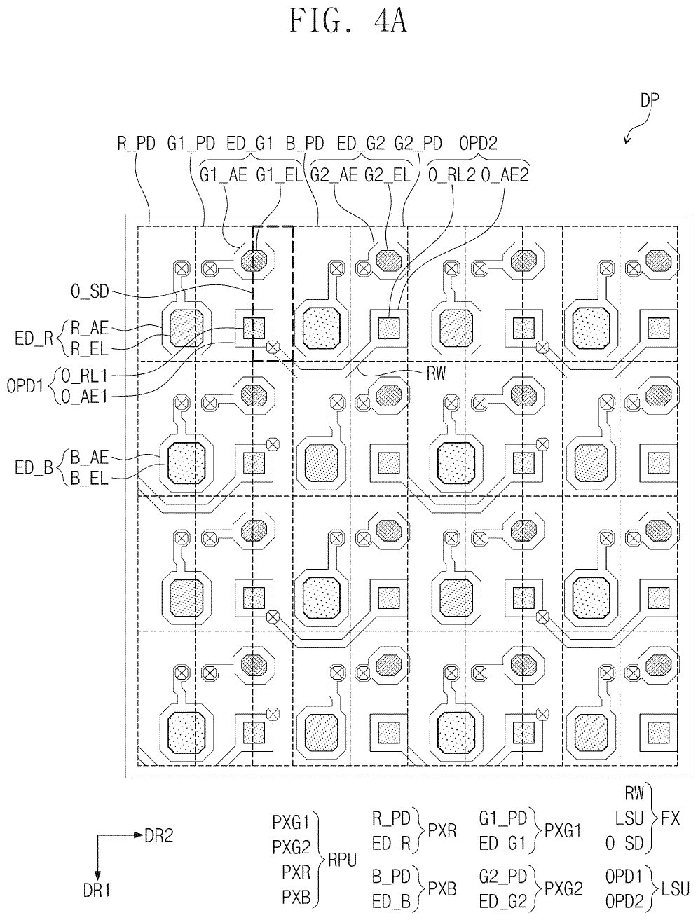

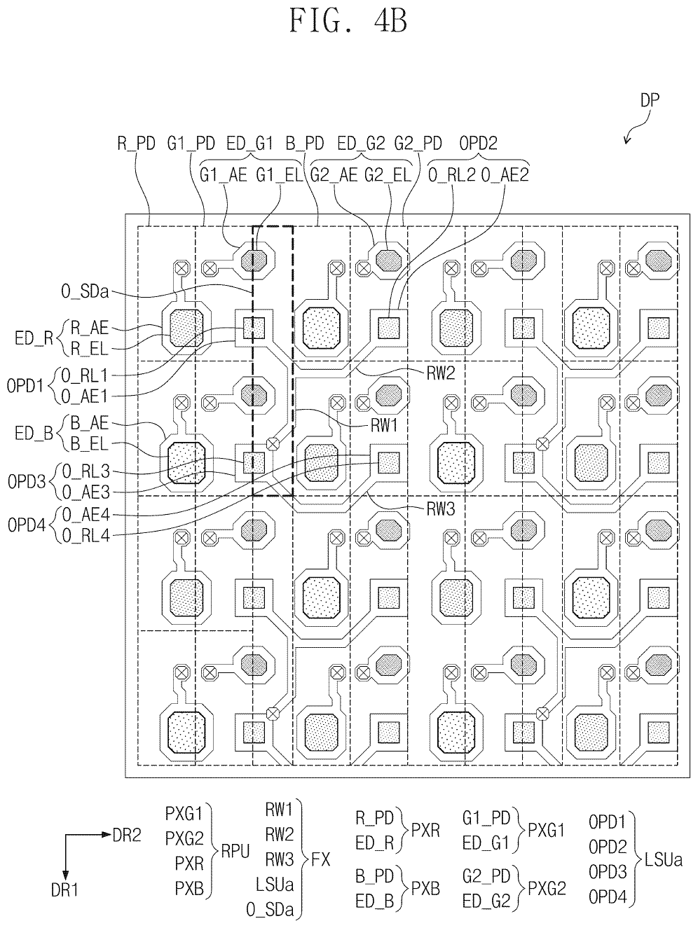

FIGS. 4A and 4B are enlarged plan views of partial regions of a display panel according to embodiments of the present disclosure.

Referring to FIG. 4A, the display panel DP may include a plurality of pixels PXR, PXG1, PXG2, and PXB and a plurality of sensors FX.

The plurality of pixels PXR, PXG1, PXG2, and PXB may be grouped into a plurality of reference pixel units RPU. According to one or more embodiments of the present disclosure, each reference pixel unit RPU may include four pixels, such as two first pixels PXG1 and PXG2 (hereinafter referred to as first and second green pixels), a third pixel PXR (hereinafter referred to as a red pixel), and a fourth pixel PXB (hereinafter referred to as a blue pixel). However, the number of the pixels included in each reference pixel unit RPU is not limited thereto. Alternatively, each reference pixel unit RPU may include three pixels, such as a first green pixel PXG1 (or a second green pixel PXG2), a red pixel PXR, and a blue pixel PXB.

The first and second green pixels PXG1 and PXG2 respectively include first and second light-emitting elements ED_G1 and ED_G2 (hereinafter referred to as first and second green light-emitting elements), the red pixel PXR may include a third light-emitting element ED_R (hereinafter referred to as a red light-emitting element), and the blue pixel PXB may include a fourth light-emitting element ED_B (hereinafter referred to as a blue light-emitting element). According to one or more embodiments of the present disclosure, each of the first and second green light-emitting elements ED_G1 and ED_G2 may output a first color light (for example, green light), the red light-emitting element ED_R may output a second color light (e.g., red light) that is different from the first color light, and the blue light-emitting element ED_B may output a third color light (e.g., blue light) that is different from the first color light and the second color light. The green light output from the first green light-emitting element ED_G1 may have substantially the same wavelength as the green light output from the second green light-emitting element ED_G2.

In the first and second directions DR1 and DR2, the red light-emitting elements ED_R and the blue light-emitting elements ED_B may be alternately and repeatedly arranged with each other. The first and second green light-emitting elements ED_G1 and ED_G2 may be alternately and repeatedly arranged in the first direction DR1, and alternately and repeatedly arranged in the second direction DR2. In the first and second directions DR1 and DR2, the first and second green light-emitting elements ED_G1 and ED_G2 may be arranged in rows and columns that are different from those of the red light-emitting elements ED_R and the blue light-emitting elements ED_B.

According to one or more embodiments of the present disclosure, the red light-emitting element ED_R may have a larger size than the first and second green light-emitting elements ED_G1 and ED_G2. In addition, the blue light-emitting element ED_B may have a size that is larger than or equal to that of the red light-emitting element ED_R. The size of each of the light-emitting elements ED_R, ED_G1, ED_G2, and ED_B is not limited thereto and may be variously modified and applied. For example, in one or more embodiments of the present disclosure, the light-emitting elements ED_R, ED_G1, ED_G2, and ED_B may have substantially the same size as each other.

The first and second green light-emitting elements ED_G1 and ED_G2 may have a shape that is different from the shapes of the red and blue light-emitting elements ED_R and ED_B. According to one or more embodiments of the present disclosure, each of the red and blue light-emitting elements ED_R and ED_B may have an octagonal shape that is longer in the first direction DR1 than in the second direction DR2. The red and blue light-emitting elements ED_R and ED_B may have substantially the same size, or may have different respective sizes. The red and blue light-emitting elements ED_R and ED_B may have substantially the same shape as each other, or may have different respective shapes. The shape of each of the red and blue light-emitting elements ED_R and ED_B is not limited thereto. For example, each of the red and blue light-emitting elements ED_R and ED_B may have an octagonal shape having substantially the same length in the first direction DR1 and the second direction DR2, or may have one of a square shape and a rectangular shape.

Each of the first and second green light-emitting elements ED_G1 and ED_G2 may have an octagonal shape that is longer in the second direction DR2 than in the first direction DR1. According to one or more embodiments of the present disclosure, the first and second green light-emitting elements ED_G1 and ED_G2 may have substantially the same size and shape as each other. However, the shapes of the first and second green light-emitting elements ED_G1 and ED_G2 are not limited thereto. Each of the first and second green light-emitting elements ED_G1 and ED_G2 may have an octagonal shape having substantially the same length in the first direction DR1 and the second direction DR2, or may have one of a square shape and a rectangular shape.

The first green light-emitting element ED_G1 may be electrically connected to a first green pixel-driving circuit G1_PD. For example, the first green light-emitting element ED_G1 may include a first green anode electrode G1_AE and a first green light-emitting layer G1_EL, and the first green anode electrode G1_AE may be connected to the first green pixel-driving circuit G1_PD through a contact hole.

The second green light-emitting element ED_G2 may be electrically connected to a second green pixel-driving circuit G2_PD. For example, the second green light-emitting element ED_G2 may include a second green anode electrode G2_AE and a second green light-emitting layer G2_EL, and the second green anode electrode G2_AE may be connected to the second green pixel-driving circuit G2_PD through a contact hole.

The first green light-emitting layer G1_EL and the second green light-emitting layer G2_EL may have substantially the same size as each other. The first green light-emitting layer G1_EL and the second green light-emitting layer G2_EL may have substantially the same or different shapes. According to one or more embodiments of the present disclosure, the first green light-emitting layer G1_EL and the second green light-emitting layer G2_EL may have different shapes on substantially the same plane. The first green anode electrode G1_AE and the second green anode electrode G2_AE may have different sizes and shapes.

The red light-emitting element ED_R may be electrically connected to a red pixel-driving circuit R_PD. For example, the red light-emitting element ED_R may include a red anode electrode R_AE and a red light-emitting layer R_EL, and the red anode electrode R_AE may be connected to the red pixel-driving circuit R_PD through a contact hole. The blue light-emitting element ED_B may be electrically connected to a blue pixel-driving circuit B_PD. For example, the blue light-emitting element ED_B may include a blue anode electrode B_AE and a blue light-emitting layer B_EL, and the blue anode electrode B_AE may be connected to the blue pixel-driving circuit B_PD through a contact hole.

Each of the sensors FX may include a light-sensing unit LSU and a sensor-driving circuit O_SD. The light-sensing unit LSU may include at least one light-receiving element. According to one or more embodiments of the present disclosure, the light-sensing unit LSU may include k light-receiving elements, and one of the k light-receiving elements may be connected to the sensor-driving circuit. Here, k may be a natural number greater than or equal to 1. FIG. 4A illustrates a case in which k is 2. When k is 2, the light-sensing unit LSU may include two light-receiving elements (hereinafter referred to as first and second light-receiving elements OPD1 and OPD2). According to one or more embodiments of the present disclosure, two light-receiving elements (for example, first and second light-receiving elements OPD1 and OPD2) may be located to correspond to one reference pixel unit RPU. However, the number of the light-receiving elements located to correspond to each reference pixel unit RPU is not limited thereto. For example, one light-receiving element may be located to correspond to each reference pixel unit RPU.

Each of the first and second light-receiving elements OPD1 and OPD2 may be located between the red and blue light-emitting elements ED_R and ED_B in the second direction DR2. Each of the first and second light-receiving elements OPD1 and OPD2 may be located adjacent to the first green light-emitting element ED_G1 or the second green light-emitting element ED_G2 in the first direction DR1. In a first reference pixel unit row, the first light-receiving element OPD1 and the first green light-emitting element ED_G1 may be adjacent to each other in the first direction DR1, and the second light-receiving element OPD2 and the second green light-emitting element ED_G2 may be adjacent to each other in the first direction DR1. In a second reference pixel unit row, the first light-receiving element OPD1 and the second green light-emitting element ED_G2 may be adjacent to each other in the first direction DR1, and the second light-receiving element OPD2 and the first green light-emitting element ED_G1 may be adjacent to each other in the first direction DR1. According to one or more embodiments of the present disclosure, each of the first and second light-receiving elements OPD1 and OPD2 may be located between the first and second green light-emitting elements ED_G1 and ED_G2, and may be adjacent to each other in the first direction DR1.

The first and second light-receiving elements OPD1 and OPD2 may have substantially the same size and shape as each other. Each of the first and second light-receiving elements OPD1 and OPD2 may have a smaller size than the red and blue light-emitting elements ED_R and ED_B. According to one or more embodiments of the present disclosure, each of the first and second light-receiving elements OPD1 and OPD2 may have a size that is smaller than, or that is equal to, the size of the first and second green light-emitting elements ED_G1 and ED_G2. However, the size of each of the first and second light-receiving elements OPD1 and OPD2 is not limited, and may be variously modified and applied. Each of the first and second light-receiving elements OPD1 and OPD2 may have a shape different from those of the red and blue light-emitting elements ED_R and ED_B. According to one or more other embodiments of the present disclosure, each of the first and second light-receiving elements OPD1 and OPD2 may have a square shape. The shape of each of the first and second light-receiving elements OPD1 and OPD2 is not limited thereto. Alternatively, each of the first and second light-receiving elements OPD1 and OPD2 may have a rectangular shape that is longer in the first direction DR1 than in the second direction DR2.

The sensor-driving circuit O_SD may be connected to one of the first or second light-receiving elements OPD1 or OPD2 (e.g., the first light-receiving element OPD1). The sensor-driving circuit O_SD may have substantially the same length as the red and blue pixel-driving circuits R_PD and B_PD in the first direction DR1. The sensor-driving circuit O_SD may overlap one of the first or second light-receiving elements OPD1 or OPD2 (e.g., the first light-receiving element OPD1) on a plane. The sensor-driving circuit O_SD may overlap one of the first or second green light-emitting elements ED_G1 or ED_G2 (e.g., the first green light-emitting element ED_G1) on a plane.

The first light-receiving element OPD1 may include a first sensing anode electrode O_AE1 and a first photoelectric conversion layer O_RL1, and the second light-receiving element OPD2 may include a second sensing anode electrode O_AE2 and a second photoelectric conversion layer O_RL2. The first sensing anode electrode O_AE1 may be directly connected to the sensor-driving circuit O_SD through a contact hole.

Each of the sensors FX may further include a routing line RW electrically connecting the first and second light-receiving elements OPD1 and OPD2 to each other. The routing line RW may be electrically connected to the first sensing anode electrode O_AE1 and the second sensing anode electrode O_AE2. According to one or more embodiments of the present disclosure, the routing line RW may be formed integrally with the first sensing anode electrode O_AE1 and the second sensing anode electrode O_AE2.

The routing line RW, the first sensing anode electrode O_AE1, and the second sensing anode electrode O_AE2 may be located on the same layer as the anode electrodes R_AE, G1_AE, G2_AE, and B_AE. In this case, the routing line RW, the first sensing anode electrode O_AE1, and the second sensing anode electrode O_AE2 may contain substantially the same material as the anode electrodes R_AE, G1_AE, G2_AE, and B_AE, and may be provided through substantially the same process as the anode electrodes R_AE, G1_AE, G2_AE, and B_AE.

The first and second light-receiving elements OPD1 and OPD2 may be connected in parallel to the sensor-driving circuit O_SD by the routing line RW. Accordingly, the first and second light-receiving elements OPD1 and OPD2 may be concurrently or substantially simultaneously turned on or turned off by the sensor-driving circuit O_SD. The first light-receiving element OPD1 connected to the sensor-driving circuit O_SD may be referred to as a main light-receiving element. The second light-receiving element OPD2 electrically connected to the first light-receiving element OPD1 through the routing line RW may be referred to as a dummy light-receiving element.

When k is 4 as illustrated in FIG. 4B, a light-sensing unit LSUa may include four light-receiving elements (hereinafter referred to as first to fourth light-receiving elements OPD1, OPD2, OPD3, and OPD4). One of the first to fourth light-receiving elements OPD1, OPD2, OPD3, and OPD4 (e.g., the third light-receiving element OPD3) may be connected to a sensor-driving circuit O_SDa.

Each of the sensors FX may further include three routing lines (hereinafter referred to as first to third routing lines RW1, RW2, and RW3) electrically connecting the first to fourth light-receiving elements OPD1, OPD2, OPD3, and OPD4 to each other. The first routing line RW1 may electrically connect two light-receiving elements (e.g., first and third light-receiving elements OPD1 and OPD3) adjacent to each other in the first direction DR1 among the four light-receiving elements OPD1, OPD2, OPD3, and OPD4. The second routing line RW2 may electrically connect two light-receiving elements (e.g., first and second light-receiving elements OPD1 and OPD2) adjacent to each other in the second direction DR2 among the four light-receiving elements OPD1, OPD2, OPD3, and OPD4. The third routing line RW3 may electrically connect two light-receiving elements (e.g., third and fourth light-receiving elements OPD3 and OPD4) adjacent to each other in the second direction DR2 among the four light-receiving elements OPD1, OPD2, OPD3, and OPD4. The third light-receiving element OPD3 directly connected to the sensor-driving circuit O_SDa may be referred to as a main light-receiving element. The remaining first, second, and fourth light-receiving elements OPD1, OPD2, and OPD4 may be referred to as dummy light-receiving elements.

The first light-receiving element OPD1 may include a first sensing anode electrode O_AE1 and a first photoelectric conversion layer O_RL1. The second light-receiving element OPD2 may include a second sensing anode electrode O_AE2 and a second photoelectric conversion layer. O_RL2. The third light-receiving element OPD3 may include a third sensing anode electrode O_AE3 and a third photoelectric conversion layer O_RL3. The fourth light-receiving element OPD4 may include a fourth sensing anode electrode O_AE4 and a fourth photoelectric conversion layer O_RL4. The third sensing anode electrode O_AE3 may be directly connected to the sensor-driving circuit O_SDa through a contact hole. The sensor-driving circuit O_SDa may have a length greater than those of the red and blue pixel-driving circuits R_PD and B_PD in the first direction DR1. Accordingly, the sensor-driving circuit O_SDa may be located to overlap two of the first to fourth light-receiving elements OPD1 to OPD4 (e.g., the first and third light-receiving elements OPD1 and OPD3) on a plane. The sensor-driving circuit O_SDa may overlap two green light-emitting elements (e.g., the first and second green light-emitting elements ED_G1 and ED_G2) on a plane.

The first routing line RW1 may be electrically connected to the first sensing anode electrode O_AE1 and the third sensing anode electrode O_AE3. The second routing line RW2 may be electrically connected to the first sensing anode electrode O_AE1 and the second sensing anode electrode O_AE2. The third routing line RW3 may be electrically connected to the third sensing anode electrode O_AE3 and the fourth sensing anode electrode O_AE4. According to one or more embodiments of the present disclosure, the first to third routing lines RW1 to RW3 may be formed integrally with the first to fourth sensing anode electrodes O_AE1 to O_AE4.

The first to third routing lines RW1, RW2, and RW3 and the first to fourth sensing anode electrodes O_AE1 to O_AE4 may be located on the same layer as the anode electrodes R_AE, G1_AE, G2_AE, and B_AE. In this case, the first to third routing lines RW1, RW2, and RW3 and the first to fourth sensing anode electrodes O_AE1 to O_AE4 may contain substantially the same material as the anode electrodes R_AE, G1_AE, G2_AE, and B_AE, and may be provided through substantially the same process as the anode electrodes R_AE, G1_AE, G2_AE, and B_AE.

The first to fourth light-receiving elements OPD1, OPD2, OPD3, and OPD4 may be connected in parallel to the sensor-driving circuit O_SDa by the first to third routing lines RW1, RW2, and RW3. Accordingly, the first to fourth light-receiving elements OPD1, OPD2, OPD3, and OPD4 may be concurrently or substantially simultaneously turned on or turned off by the sensor-driving circuit O_SDa.

The sensor-driving circuits O_SD and O_SDa may include a plurality of transistors. According to one or more embodiments of the present disclosure, the sensor-driving circuits O_SD and O_SDa and the pixel-driving circuits R_PD, G1_PD, G2_PD, and B_PD may be concurrently or substantially simultaneously formed through substantially the same process as each other. In addition, the scan driver 300 (see FIG. 3) may include transistors formed through substantially the same process as the sensor-driving circuits O_SD and O_SDa and the pixel-driving circuits R_PD, G1_PD, G2_PD, and B_PD.

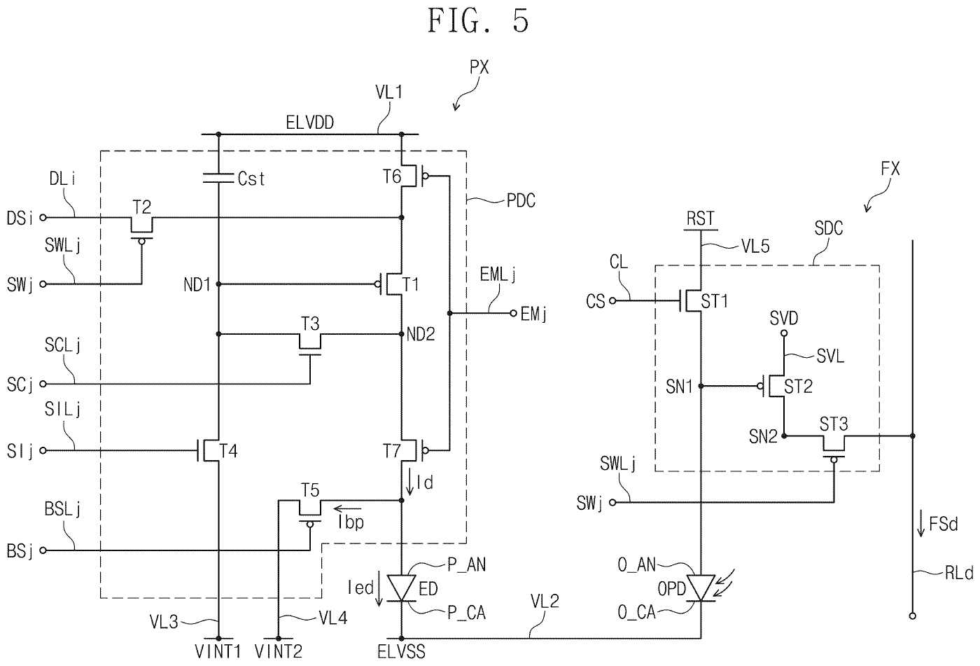

FIG. 5 is a circuit diagram illustrating a pixel and a sensor of the display panel according to one or more embodiments of the present disclosure.

FIG. 5 illustrates an equivalent circuit diagram of one pixel PX among the plurality of pixels PX illustrated in FIG. 3. Because the plurality of pixels PX have substantially the same circuit structure as each other and the circuit structure of the pixel PX is described below, a detailed description of the remaining pixels will be omitted.

In addition, FIG. 5 illustrates an equivalent circuit diagram of one sensor FX among the plurality of sensors FX illustrated in FIG. 3. Because the plurality of sensors FX have substantially the same circuit structure as each other and the circuit structure of the sensor FX is described below, a detailed description of the remaining sensors will be omitted.

Referring to FIG. 5, the pixel PX may be connected to an i-th data line DLi among the data lines DL1 to DLm (see FIG. 3), a j-th initialization scan line SILj among the initialization scan lines SIL1 to SILn (see FIG. 3), a j-th compensation scan line SCLj among the compensation scan lines SCL1 to SCLn (see FIG. 3), a j-th write scan line SWLj among the write scan lines SWL1 to SWLn (see FIG. 3), a j-th black scan line BSLj among the black scan lines BSL1 to BSLn (see FIG. 3), and a j-th light-emitting control line EMLj among the light-emitting control lines EML1 to EMLn (see FIG. 3).

The pixel PX may include a light-emitting element ED and a pixel-driving circuit PDC. The light-emitting element ED may be a light-emitting diode. According to one or more embodiments of the present disclosure, the light-emitting element ED may be an organic light-emitting diode including an organic light-emitting layer. The pixel-driving circuit PDC may be electrically connected to the light-emitting element ED to control the operation of the light-emitting element ED.

The pixel-driving circuit PDC may include first to seventh transistors T1, T2, T3, T4, T5, T6, and T7 and one capacitor Cst. At least one of the first to seventh transistors T1, T2, T3, T4, T5, T6, or T7 may have a low-temperature polycrystalline silicon (LTPS) semiconductor layer. At least one of the first to seventh transistors T1, T2, T3, T4, T5, T6, or T7 may have an oxide semiconductor layer. One or more of the first to seventh transistors T1, T2, T3, T4, T5, T6, or T7 may be P-type transistors, and one or more others thereof may be N-type transistors. For example, the first, second, fifth, sixth, and seventh transistors T1, T2, T5, T6, and T7 may be PMOS transistors, and the third and fourth transistors T3 and T4 may be NMOS transistors. For example, the third and fourth transistors T3 and T4 may be oxide semiconductor transistors, and the first, second, fifth, sixth, and seventh transistors T1, T2, T5, T6, and T7 may be low-temperature polysilicon semiconductor transistors.

The configuration of the pixel-driving circuit PDC according to one or more embodiments of the present disclosure is not limited to the embodiment illustrated in FIG. 5. The pixel-driving circuit PDC illustrated in FIG. 5 is just an example, and the configuration of the pixel-driving circuit PDC may be modified. For example, all of the first to seventh transistors T1, T2, T3, T4, T5, T6, and T7 may be P-type transistors or N-type transistors.

The j-th initialization scan line SILj, the j-th compensation scan line SCLj, the j-th write scan line SWLj, the j-th black scan line BSLj, and the j-th light-emitting control line EMLj may respectively transmit a j-th initialization scan signal Slj, a j-th compensation scan signal SCj, a j-th write scan signal SWj, a j-th black scan signal BSj, and a j-th light-emitting control signal EMj to the pixel PX. The i-th data line DLi may transmit an i-th data signal DSi to the pixel PX. The i-th data signal DSi may have a voltage level corresponding to the image signal RGB (see FIG. 3) input to the display device DD (see FIG. 3).

First and second driving voltage lines VL1 and VL2 may respectively transmit the first driving voltage ELVDD and the second driving voltage ELVSS to the pixel PX. In addition, first and second initialization voltage lines VL3 and VL4 may respectively transmit the first initialization voltage VINT1 and the second initialization voltage VINT2 to the pixel PX.

The first transistor T1 may be connected between the light-emitting element ED and the first driving voltage line VL1 that receives the first driving voltage ELVDD. The first transistor T1 may include a first electrode connected to the first driving voltage line VL1 via the sixth transistor T6, a second electrode connected to a pixel anode electrode P_AN of the light-emitting element ED via the seventh transistor T7, and a third electrode connected to one end of the capacitor Cst (for example, one end connected to a first node ND1). The first transistor T1 may receive the i-th data signal DSi transmitted by the i-th data line DLi according to the switching operation of the second transistor T2, and may supply a driving current Id to the light-emitting element ED.

The second transistor T2 may be connected between the data line DLi and the first electrode of the first transistor T1. The second transistor T2 may include a first electrode connected to the data line DLi, a second electrode connected to the first electrode of the first transistor T1, and a third electrode connected to the j-th write scan line SWLj. The second transistor T2 may be turned on according to the write scan signal SWj received through the j-th write scan line SWLj, and may then transmit the i-th data signal DSi, which may be transmitted from the i-th data line DLi, to the first electrode of the transistor T1.

The third transistor T3 may be connected between the second electrode of the first transistor T1 and the first node ND1. The third transistor T3 may include a first electrode connected to the third electrode of the first transistor T1, a second electrode connected to the second electrode of the first transistor T1, and a third electrode connected to the j-th compensation scan line SCLj. The third transistor T3 may be turned on according to the j-th compensation scan signal SCj received through the j-th compensation scan line SCLj, and may connect the third electrode and the second electrode of the first transistor T1 to each other, thus being able to diode-connect the first transistor T1.

The fourth transistor T4 may be connected between the first node ND1 and the first initialization voltage line VL3 to which the first initialization voltage VINT1 may be applied. The fourth transistor T4 may include a first electrode connected to the first initialization voltage line VL3, a second electrode connected to the first node ND1, and a third electrode connected to the j-th initialization scan line SILj. The fourth transistor T4 may be turned on according to the j-th initialization scan signal Slj received through the j-th initialization scan line SILj. The turned-on fourth transistor T4 transmits the first initialization voltage VINT1 to the first node ND1 to initialize the potential (e.g., the potential of the first node ND1) of the third electrode of the first transistor T1.

The sixth transistor T6 may include a first electrode connected to the first driving voltage line VL1, a second electrode connected to the first electrode of the first transistor T1, and a third electrode connected to the j-th light-emitting control line EMLj.

The seventh transistor T7 may include a first electrode connected to the second electrode of the first transistor T1, a second electrode connected to the pixel anode electrode P_AN of the light-emitting element ED, and a third electrode connected to the j-th light-emitting control line EMLj.

The sixth and seventh transistors T6 and T7 are concurrently or substantially simultaneously turned on according to the j-th light-emitting control signal EMj received through the j-th light-emitting control line EMLj. The first driving voltage ELVDD applied through the turned-on sixth transistor T6 may be compensated through the diode-connected first transistor T1 and then transmitted to the light-emitting element ED.

The fifth transistor T5 may include a first electrode connected to the second initialization voltage line VL4 to which the second initialization voltage VINT2 may be transmitted, a second electrode connected to the second electrode of the seventh transistor T7, and a third electrode connected to the black scan line BSLj. The second initialization voltage VINT2 may have a voltage level that is lower than or equal to that of the first initialization voltage VINT1.

As described above, one end of the capacitor Cst may be connected to the third electrode of the first transistor T1, and the other end thereof may be connected to the first driving voltage line VL1.

A pixel cathode electrode P_CA of the light-emitting element ED may be connected to the second driving voltage line VL2, which transmits the second driving voltage ELVSS. The second driving voltage ELVSS may have a lower voltage level than the first driving voltage ELVDD. According to one or more embodiments of the present disclosure, the second driving voltage ELVSS may have a lower voltage level than the first and second initialization voltages VINT1 and VINT2.

According to one or more embodiments of the present disclosure, within one driving frame of the display panel DP (see FIG. 3), the j-th light-emitting control signal EMj may include a light-emitting period and a non-light-emitting period. The j-th light-emitting control signal EMj may have a high level during the non-light-emitting period. Within the non-light-emitting period, the j-th initialization scan signal Slj may be activated. During an activation period (hereinafter, a first activation period) of the j-th initialization scan signal Slj, when the j-th initialization scan signal Slj having a high level is provided through the j-th initialization scan line SILj, the fourth transistor T4 may be turned on in response to the first initialization scan signal Slj having the high level. The first initialization voltage VINT1 may be transmitted to the third electrode of the first transistor T1 through the turned-on fourth transistor T4, and the first node ND1 may be initialized by the first initialization voltage VINT1. Accordingly, the first activation period may be defined as an initialization period of the pixel PX.

Next, when the j-th compensation scan signal SCj is activated and the j-th compensation scan signal SCj having a high level is supplied through the j-th compensation scan line SCLj during an activation period (hereinafter, a second activation period) of the j-th compensation scan signal SCj, the third transistor T3 may be turned on. The first transistor T1 may be diode-connected by the turned-on third transistor T3 and biased in a forward direction. The first activation period may not overlap the second activation period.

The j-th write scan signal SWj may be activated within the second activation period. The j-th write scan signal SWj has a low level during an activation period (hereinafter, a fourth activation period). During the fourth activation period, the second transistor T2 may be turned on by the j-th write scan signal SWj having the low level. Then, in the i-th data signal DSi supplied from the i-th data line DLi, a compensation voltage, which may be reduced by about as much as a threshold voltage Vth of the first transistor T1, may be applied to the third electrode of the first transistor T1. For example, the potential of the third electrode of the first transistor T1 may be the compensation voltage. The fourth activation period may overlap the second activation period. The duration of the second activation period may be greater than the duration of the fourth activation period.

The first driving voltage ELVDD and the compensation voltage may be applied to both ends of the capacitor Cst. A charge corresponding to a voltage difference between both ends of the capacitor Cst may be stored in the capacitor Cst. Here, the high-level period of the j-th compensation scan signal SCj may be referred to as a compensation period of the pixel PX.

The j-th black scan signal BSj may be activated within the second activation period of the j-th compensation scan signal SCj. The j-th black scan signal BSj may have a low level during an activation period (hereinafter, a third activation period). During the third activation period, the fifth transistor T5 may be turned on by receiving the j-th black scan signal BSj having the low level through the j-th black scan line BSLj. A portion of the driving current Id may escape through the fifth transistor T5 as a bypass current Ibp. The third activation period may overlap the second activation period. The duration of the second activation period may be greater than the duration of the third activation period. The third activation period may precede the fourth activation period, and may not overlap the fourth activation period.

In a case in which the pixel PX displays a black image, when the light-emitting element ED emits light although a minimum driving current of the first transistor T1 flows as the driving current Id, the pixel PX may not normally display the black image. Therefore, the fifth transistor T5 according to one or more embodiments of the present disclosure may disperse a portion of the minimum driving current of the first transistor T1 as the bypass current Ibp to another current path besides a current path toward the light-emitting element ED. When the minimum driving current is applied to the first transistor T1, a leakage current may flow to the first transistor T1 if a gate-source voltage of the first transistor T1 is lower than the threshold voltage so that the first transistor T1 is turned off. If the first transistor T1 is turned off, the minimum driving current (for example, a current of about 10 pA or less) flowing to the first transistor T1 may be transmitted to the light-emitting element ED, and a black grayscale image may be displayed. When the pixel PX displays a black image, the influence of the bypass current Ibp on the minimum driving current is relatively great. When the pixel PX displays an image, such as a general image or a white image, there may be almost no influence of the bypass current Ibp on the driving current Id. Therefore, when a black image is displayed, a current (e.g., a light-emitting current led) that is reduced by as much as the current amount of the bypass current Ibp, which is removed from the driving current Id and passes through the fifth transistor T5, may be transmitted to the light-emitting element ED, so that the black image may be suitably displayed. Accordingly, the pixel PX may implement an accurate black grayscale image by using the fifth transistor T5, and as a result, a contrast ratio may be improved.

Next, the j-th light-emitting control signal EMj supplied from the j-th light-emitting control line EMLj may be changed from a high level to a low level. Each of the sixth and seventh transistors T6 and T7 may be turned on by the light-emitting control signal EMj having the low level. Then, a driving current Id may be generated according to a voltage difference between the voltage of the third electrode of the first transistor T1 and the first driving voltage ELVDD. The driving current Id may be supplied to the light-emitting element ED through the seventh transistor T7, so that a current led flows through the light-emitting element ED.

Referring to FIG. 5, the sensor FX may be connected to a d-th sensing line RLd among the sensing lines RL1 to RLh (see FIG. 3), a j-th write scan line SWLj, and a sensing control line CL.

The sensor FX may include a light-receiving element OPD and a sensing-driving circuit SDC. The light-receiving element OPD may be a photodiode. According to one or more embodiments of the present disclosure, the light-receiving element OPD may be an organic photodiode, which may include an organic material, as a photoelectric conversion layer. An anode electrode O_AN (hereinafter referred to as a sensing anode electrode) of the light-receiving element OPD may be connected to a first sensing node SN1. A cathode electrode O_CA (hereinafter referred to as a sensing cathode electrode) of the light-receiving element OPD may be connected to the second driving voltage line VL2, which transmits the second driving voltage ELVSS. The sensing-driving circuit SDC may be electrically connected to the light-receiving element OPD to control the operation of the light-receiving element OPD.

The sensing-driving circuit SDC may include three transistors ST1 to ST3. The three transistors ST1 to ST3 may be a reset transistor ST1, an amplification transistor ST2, and an output transistor ST3, respectively. At least one of the reset transistor ST1, the amplification transistor ST2, or the output transistor ST3 may be an oxide semiconductor transistor. According to one or more embodiments of the present disclosure, the reset transistor ST1 may be an oxide semiconductor transistor, and the amplification transistor ST2 and the output transistor ST3 may be LTPS transistors. Without being limited thereto, however, and for example, at least the reset transistor ST1 and the output transistor ST3 may be oxide semiconductor transistors, and the amplification transistor ST2 may be an LTPS transistor.

In addition, one or more of the reset transistor ST1, the amplification transistor ST2, or the output transistor ST3 may be P-type transistors, and others thereof may be N-type transistors. According to one or more embodiments of the present disclosure, the amplification transistor ST2 and the output transistor ST3 may be P-type transistors, and the reset transistor ST1 may be an N-type transistor. Without being limited thereto, however, and for example all of the reset transistor ST1, the amplification transistor ST2, and the output transistor ST3 may be N-type transistors, or all of them may be P-type transistors, in one or more other embodiments.

One or more of the reset transistor ST1, the amplification transistor ST2, or the output transistor ST3 (e.g., the reset transistor ST1) may be transistors of substantially the same type as the third and fourth transistors T3 and T4 of the pixel PX. The amplification transistor ST2 and the output transistor ST3 may be transistors of substantially the same type as the first, second, fifth, sixth, and seventh transistors T1, T2, T5, T6, and T7 of the pixel PX.

The circuit configuration of the sensing-driving circuit SDC according to one or more embodiments of the present disclosure is not limited to the circuit configuration of FIG. 5. The sensing-driving circuit SDC illustrated in FIG. 5 is only one example, and the configuration of the sensing-driving circuit SDC may be modified and implemented.

The reset transistor ST1 may include a first electrode connected to a reset-receiving line VL5 that receives a reset voltage RST, a second electrode connected to the first sensing node SN1, and a third electrode connected to the sensing control line CL that receives a sensing control signal CS. The reset transistor ST1 may reset the potential of the first sensing node SN1 to the reset voltage RST in response to the sensing control signal CS. According to one or more embodiments of the present disclosure, the sensing control signal CS may be the j-th compensation scan signal SCj supplied from the j-th compensation scan line SCLj. In this case, the sensing control line CL may be electrically connected to the j-th compensation scan line SCLj. For example, the reset transistor ST1 may receive the j-th compensation scan signal SCj supplied from the j-th compensation scan line SCLj as the sensing control signal CS. However, the present disclosure is not limited thereto. The sensing control line CL may be electrically insulated from the scan lines SWLj, SCLj, SILj, and BSLj. Alternatively, the sensing control signal CS may be a signal separate from the j-th compensation scan signal SCj. A timing at which the sensing control signal CS is activated, and a timing at which the j-th compensation scan signal SCj is activated, may be different from each other.

According to one or more embodiments of the present disclosure, the reset voltage RST may be a DC voltage that is maintained at a voltage level that is lower than the second driving voltage ELVSS. However, the present disclosure is not limited thereto. The reset voltage RST may have a voltage level that is lower than the second driving voltage ELVSS at least during the activation period of the sensing control signal CS. According to one or more other embodiments of the present disclosure, the reset voltage RST may be generated to be the same voltage as any one of the first or second initialization voltages VINT1 or VINT2.

The reset transistor ST1 may include a plurality of sub-reset transistors connected to each other in series. For example, the reset transistor ST1 may include two sub-reset transistors (hereinafter referred to as first sub-reset transistor and second sub-reset transistor). In this case, a third electrode of the first sub-reset transistor, and a third electrode of the second sub-reset transistor, may be connected to the sensing control line CL. In addition, a second electrode of the first sub-reset transistor may be electrically connected to a first electrode of the second sub-reset transistor. In addition, the reset voltage RST may be applied to a first electrode of the first sub-reset transistor, and a second electrode of the second sub-reset transistor may be electrically connected to the first sensing node SN1. However, the number of the sub-reset transistors is not limited thereto and may be variously modified.

The amplification transistor ST2 may include a first electrode connected to a sensing-driving line SVL that receives a sensing-driving voltage SVD, a second electrode connected to a second sensing node SN2, and a third electrode connected to the first sensing node SN1. The amplification transistor ST2 may be turned on according to the potential of the first sensing node SN1 so that the sensing-driving voltage SVD may be applied to the second sensing node SN2. According to one or more embodiments of the present disclosure, the sensing-driving voltage SVD may be one of the first driving voltage ELVDD or the first or second initialization voltages VINT1 or VINT2. When the sensing-driving voltage SVD is the first driving voltage ELVDD, the sensing-driving line SVL may be electrically connected to the first driving voltage line VL1. When the sensing-driving voltage SVD is the first initialization voltage VINT1, the sensing-driving line SVL may be electrically connected to the first initialization voltage line VL3. When the sensing-driving voltage SVD is the second initialization voltage VINT2, the sensing-driving line SVL may be electrically connected to the second initialization voltage line VL4.

The output transistor ST3 may include a first electrode connected to the second sensing node SN2, a second electrode connected to the d-th sensing line RLd, and a third electrode connected to an output control line that receives an output control signal. The output transistor ST3 may transmit a d-th sensing signal FSd to the d-th sensing line RLd in response to the output control signal. The output control signal may be the j-th write scan signal SWj supplied through the j-th write scan line SWLj. For example, the output transistor ST3 may receive the j-th write scan signal SWj supplied from the j-th write scan line SWLj as the output control signal.

The light-receiving element OPD of the sensor FX may be exposed to light emitted from the light-emitting element ED. According to one or more embodiments of the present disclosure, the light-receiving element OPD may generate photo-charges corresponding to the received light, and the generated photo-charges may be accumulated in the first sensing node SN1. For example, when the hand US_F (see FIG. 1) of the user touches the display surface IS (see FIG. 1) of the display device DD (see FIG. 1) and the light-emitting element ED emits light, the light-receiving element OPD receives light reflected by the hand US_F (see FIG. 1) of the user among the light emitted from the light-emitting element ED, and may generate the photo-charges corresponding to the received reflected light.

When the output transistor ST3 is turned on, the d-th sensing signal FSd flowing from the sensing-driving line SVL to the d-th sensing line RLd through the amplification transistor ST2 and the output transistor ST3 is determined by the amount of charge of the first sensing node SN1. According to one or more embodiments of the present disclosure, when the output transistor ST3 is a P-type transistor, the larger the amount of photo-charges generated by the light-receiving element OPD and stored in the first sensing node SN1 is, the smaller the size of the d-th sensing signal FSd may be.

FIG. 6 is a cross-sectional view illustrating a pixel and a sensor of the display device according to one or more embodiments of the present disclosure.

Referring to FIG. 6, the display panel DP may include a base layer BL, a circuit layer DP_CL located on the base layer BL, an element layer DP_ED, and an encapsulation layer TFE.

The base layer BL may include a synthetic resin layer. The synthetic resin layer may contain a thermosetting resin. For example, the synthetic resin layer may be a polyimide-based resin layer, but its material is not limited thereto. The synthetic resin layer may contain at least any one of an acrylic-based resin, a methacrylic-based resin, polyisoprene, a vinyl-based resin, an epoxy-based resin, a urethane-based resin, a cellulose-based resin, a siloxane-based resin, a polyamide-based resin, or a perylene-based resin. In addition, the base layer may include a glass substrate, a metal substrate, an organic/inorganic composite material substrate, or the like.

The circuit layer DP_CL may be located on the base layer BL. According to one or more embodiments of the present disclosure, the circuit layer DP_CL may include the pixel-driving circuit PDC and the sensing-driving circuit SDC illustrated in FIG. 5. According to one or more other embodiments of the present disclosure, FIG. 6 illustrates a portion of the pixel-driving circuit PDC (see FIG. 5) included in the circuit layer DP_CL, for example, a pixel transistor P_TR. According to one or more other embodiments of the present disclosure, the pixel transistor P_TR may be electrically connected to the light-emitting element ED included in the element layer DP_ED. According to one or more other embodiments of the present disclosure, the pixel transistor P_TR may be a transistor corresponding to the seventh transistor T7 (see FIG. 5) of the pixel-driving circuit PDC (see FIG. 5) included in a pixel. However, the present disclosure is not limited thereto, and the transistor corresponding to the pixel transistor P_TR in the pixel-driving circuit PDC may vary depending on the circuit configuration of the pixel.

In addition, according to one or more embodiments of the present disclosure, FIG. 6 illustrates a partial configuration of the sensing-driving circuit SDC (see FIG. 5) included in the circuit layer DP_CL, for example, a sensor transistor O_TR. According to one or more other embodiments of the present disclosure, the sensor transistor O_TR may be a transistor corresponding to the reset transistor ST1 (see FIG. 5) of the sensing-driving circuit SDC (see FIG. 5). However, the present disclosure is not limited thereto, and the transistor corresponding to the sensor transistor O_TR in the sensing-driving circuit SDC (see FIG. 5) may vary depending on the circuit configuration of a sensor.

The element layer DP_ED may be located on the circuit layer DP_CL. According to one or more embodiments of the present disclosure, the element layer DP_ED may include a light-emitting element ED, a light-receiving element OPD, and an element-defining film PDL. According to one or more other embodiments of the present disclosure, the light-emitting element ED may include a first and second green light-emitting elements ED_G1 and ED_G2 (see FIG. 4A), a red light-emitting element ED_R (see FIG. 4A), and a blue light-emitting element ED_B (see FIG. 4A). Although the light-emitting element ED is illustrated as the light-emitting element ED in FIG. 6, the description applied to the light-emitting element ED may be equally applied to the first and second green light-emitting elements ED_G1 or ED_G2, the red light-emitting element ED_R, and the blue light-emitting element ED_B.

According to one or more embodiments of the present disclosure, the light-emitting element ED may include a pixel anode electrode P_AN (or a first pixel electrode), a pixel hole auxiliary layer P_HCL, a light-emitting layer P_EL, a pixel electron auxiliary layer P_ECL, and a pixel cathode electrode P_CA (or a second pixel electrode).

According to one or more embodiments of the present disclosure, the light-receiving element OPD may include a sensing anode electrode O_AN (or a first sensing electrode), a sensing hole auxiliary layer O_HCL, a photoelectric conversion layer PCL, a sensing electron auxiliary layer O_ECL, and a sensing cathode electrode O_CA (or a second sensing electrode).

The pixel anode electrode P_AN and the sensing anode electrode O_AN are located on the circuit layer DP_CL. The pixel anode electrode P_AN may be connected to a pixel transistor P_TR through a contact hole passing through an insulating layer included in the circuit layer DP_CL. However, the present disclosure is not limited thereto, and the pixel anode electrode P_AN may be connected to a connection electrode electrically connected to the pixel transistor P_TR through a contact hole passing through the insulating layer included in the circuit layer DP_CL. The sensing anode electrode O_AN may be connected to the sensor transistor O_TR through a contact hole passing through the insulating layer included in the circuit layer DP_CL. However, the present disclosure is not limited thereto, and the sensing anode electrode O_AN may be connected to a connection electrode electrically connected to the sensor transistor O_TR through a contact hole passing through the insulating layer included in the circuit layer DP_CL.

An element-defining film PDL is located on the circuit layer DP_CL, the pixel anode electrode P_AN, and the sensing anode electrode O_AN. A first opening OP1 of the element-defining film PDL exposes at least a portion of the pixel anode electrode P_AN. A second opening OP2 of the element-defining film PDL exposes at least a portion of the sensing anode electrode O_AN.

According to one or more embodiments of the present disclosure, a plurality of pixels PX (see FIG. 3) may be arranged in a regular pattern on the plane of the display panel DP (see FIG. 3). A region in which the plurality of pixels PX (see FIG. 3) are arranged may be defined as a pixel region, and one pixel region may include a light-emitting region PXA, and a non-light-emitting region NPXA adjacent to the light-emitting region PXA. The non-light-emitting region NPXA may surround the light-emitting region PXA.

According to one or more embodiments of the present disclosure, the light-emitting region PXA may include a green light-emitting region in which a green pixel is located, a red light-emitting region in which a red pixel is located, and a blue light-emitting region in which a blue pixel is located. According to one or more embodiments of the present disclosure, only the light-emitting region PXA is illustrated in FIG. 6, but the light-emitting region PXA may correspond to at least one of the green light-emitting region, the red light-emitting region, or the blue light-emitting region. The first opening OP1 of the element-defining film PDL may define the light-emitting region PXA.

According to one or more embodiments of the present disclosure, the non-light-emitting region NPXA may include a green non-light-emitting region adjacent to the green light-emitting region, a red non-light-emitting region adjacent to the red light-emitting region, and a blue non-light-emitting region adjacent to the blue light-emitting region. Although only the non-light-emitting region NPXA is illustrated in FIG. 6, the non-light-emitting region NPXA may correspond to at least one of the green non-light-emitting region, the red non-light-emitting region, or the blue non-light-emitting region.

According to one or more embodiments of the present disclosure, a plurality of sensors FX (see FIG. 3) may be arranged in a regular pattern on the plane of the display panel DP (see FIG. 3). A region in which a plurality of sensors FX (see FIG. 3) are arranged may be defined as a light-receiving sensing region, and one light-receiving sensing region may include a sensing region SA, and a non-sensing region NSA adjacent to the sensing region SA. According to one or more embodiments of the present disclosure, the second opening OP2 of the element-defining film PDL may define the sensing region SA. The non-sensing region NSA may surround the sensing region SA (e.g., in plan view).

In one or more embodiments of the present disclosure, the element-defining film PDL may further contain a black material. The element-defining film PDL may further contain a black organic dye/pigment, such as carbon black or aniline black. The element-defining film PDL may be formed by mixing a blue organic material and a black organic material. The element-defining film PDL may further contain a liquid-repellent organic material.

The pixel hole auxiliary layer P_HCL may be located on the pixel anode electrode P_AN. The sensing hole auxiliary layer O_HCL may be located on the sensing anode electrode O_AN. The pixel hole auxiliary layer P_HCL may be located in a region corresponding to the first opening OP1. The pixel hole auxiliary layer P_HCL may not overlap the non-light-emitting region NPXA on a plane.

The sensing hole auxiliary layer O_HCL may be located on the sensing anode electrode O_AN. The sensing hole auxiliary layer O_HCL may be located in a region corresponding to the second opening OP2. The sensing hole auxiliary layer O_HCL may not overlap the non-sensing region NSA on a plane.

According to one or more embodiments of the present disclosure, the pixel hole auxiliary layer P_HCL and the sensing hole auxiliary layer O_HCL may be electrically insulated from each other.

The light-emitting layer P_EL may be located on the pixel hole auxiliary layer P_HCL. A plurality of light-emitting layers P_EL may be located in a plurality of pixels PX. The light-emitting layer P_EL may include a first and second green light-emitting layers G1_EL and G2_EL (see FIG. 4A), a red light-emitting layer R_EL (see FIG. 4A), and a blue light-emitting layer B_EL (see FIG. 4A). FIG. 6 illustrates the light-emitting layer P_EL. The light-emitting layer P_EL may correspond to at least one of the first or second green light-emitting layer G1_EL or G2_EL (see FIG. 4A), the red light-emitting layer R_EL (see FIG. 4A), and the blue light-emitting layer B_EL (see FIG. 4A). The light-emitting layer P_EL may be located in a region corresponding to the first opening OP1.

The pixel electron auxiliary layer P_ECL may be located on the light-emitting layer P_EL. The pixel electron auxiliary layer P_ECL may be commonly located in a plurality of pixels PX (see FIG. 3). According to one or more embodiments of the present disclosure, the pixel electron auxiliary layer P_ECL may be located in the light-emitting region PXA and the non-light-emitting region NPXA. The pixel electron auxiliary layer P_ECL may include a green electron auxiliary layer, a red electron auxiliary layer, and a blue electron auxiliary layer corresponding to the first and second green light-emitting layer G1_EL and G2_EL, the red light-emitting layer R_EL, and the blue light-emitting layer B_EL. In one or more other embodiments, the green auxiliary electron layer, the red auxiliary electron layer, and the blue auxiliary electron layer may be electrically connected to each other.

The sensing electron auxiliary layer O_ECL may be located on the photoelectric conversion layer PCL. The sensing electron auxiliary layer O_ECL may be commonly located in a plurality of sensors FX (see FIG. 3). According to one or more embodiments of the present disclosure, the sensing electron auxiliary layer O_ECL may be located in the sensing region SA and the non-sensing region NSA. According to one or more other embodiments of the present disclosure, the pixel electron auxiliary layer P_ECL and the sensing electron auxiliary layer O_ECL may be electrically connected to each other. The pixel electron auxiliary layer P_ECL and the sensing electron auxiliary layer O_ECL may be formed in common through substantially the same process as each other.

The pixel cathode electrode P_CA (see FIG. 5) may be located on the pixel electron auxiliary layer P_ECL. The pixel cathode electrode P_CA (see FIG. 5) may be commonly located in a plurality of pixels PX. According to one or more embodiments of the present disclosure, the pixel cathode electrode P_CA (see FIG. 5) may be located in the light-emitting region PXA and the non-light-emitting region NPXA. The pixel cathode electrode P_CA (see FIG. 5) may include a green cathode electrode, a red cathode electrode, and a blue cathode electrode corresponding to the first and second green light-emitting layer G1_EL and G2_EL, the red light-emitting layer R_EL, and the blue light-emitting layer B_EL. In one or more other embodiments, the green cathode electrode, the red cathode electrode, and the blue cathode electrode may be electrically connected to each other.

The sensing cathode electrode O_CA may be located on the sensing electron auxiliary layer O_ECL. The sensing cathode electrode O_CA may be commonly located in a plurality of sensors FX. According to one or more embodiments of the present disclosure, the sensing cathode electrode O_CA may be located in the sensing region SA and the non-sensing region NSA. According to one or more other embodiments of the present disclosure, the pixel cathode electrode P_CA and the sensing cathode electrode O_CA may be electrically connected to each other.

The sensing cathode electrode O_CA may include a first sensing electrode layer O_CAL1 and a second sensing electrode layer O_CAL2. The first sensing electrode layer O_CAL1 may be located to overlap the sensing region and the non-sensing region. The second sensing electrode layer O_CAL2 may be located on the first sensing electrode layer O_CAL1. The second sensing electrode layer O_CAL2 may overlap the sensing region SA, and may not overlap the non-sensing region NSA. The first sensing electrode layer O_CAL1 and the second sensing electrode layer O_CAL2 may be electrically connected to each other. The thickness of the sensing cathode electrode O_CA in the sensing region SA in which the second sensing electrode layer O_CAL2 is formed may be greater than the thickness of the sensing cathode electrode O_CA in the non-sensing region NSA in which the second sensing electrode layer O_CAL2 is not formed. Details on this will be described later.

A capping layer CPL may be located on the pixel cathode electrode P_CA (see FIG. 5) and the sensing cathode electrode O_CA. The capping layer CPL may include multiple layers or a single layer. In one or more embodiments of the present disclosure, the capping layer CPL may be an organic layer or an inorganic layer. For example, when the capping layer CPL contains an inorganic material, the capping layer CPL may contain an alkali metal compound, such as MgF2, or the like. For example, when the capping layer CPL contains an organic material, the organic material may contain α-NPD, NPB, TPD, m-MTDATA, Alq3, CuPc, TPD15(N4,N4,N4′,N4′-tetra(biphenyl-4-yl) biphenyl-4,4′-diamine), TCTA (4,4′,4″-Tris(carbazol-9-yl)triphenylamine), an epoxy resin, or acrylate, such as methacrylate. However, the present disclosure is not limited thereto.

The encapsulation layer TFE may be located on the capping layer CPL. The encapsulation layer TFE may cover a plurality of pixels PX (see FIG. 3) and a plurality of sensors FX (see FIG. 3). In one or more embodiments, the encapsulation layer TFE may directly cover the capping layer CPL. The encapsulation layer TFE may include at least one inorganic layer or one organic layer. In one or more other embodiments of the present disclosure, the encapsulation layer TFE may include two inorganic layers, and an organic layer located between the two inorganic layers. In one or more other embodiments of the present disclosure, the encapsulation layer TFE may include a plurality of inorganic layers (hereinafter referred to as inorganic encapsulation layers) and a plurality of organic layers (hereinafter referred to as organic encapsulation layers) stacked alternately on top of each other. The inorganic encapsulation layer protects the light-emitting element ED and the light-receiving element OPD from moisture/oxygen. The organic encapsulation layer protects the light-emitting element ED and the light-receiving element OPD from foreign substances, such as dust particles. The inorganic encapsulation layer may include a silicon nitride layer, a silicon oxynitride layer, a silicon oxide layer, a titanium oxide layer, an aluminum oxide layer, or the like, but the present disclosure is not limited thereto. The organic encapsulation layer may include an acrylic-based organic layer, but the present disclosure is not limited thereto.

The input-sensing layer ISL may be directly located on the encapsulation layer TFE. The input-sensing layer ISL may include a first conductive layer ICL1, a first insulating layer IIL1, a second conductive layer ICL2, and a second insulating layer IIL2. The first conductive layer ICL1 may be located on the encapsulation layer TFE. Although FIG. 6 illustrates a structure in which the first conductive layer ICL1 is directly located on the encapsulation layer TFE, the present disclosure is not limited thereto. The input-sensing layer ISL may further include a base insulating layer located between the first conductive layer ICL1 and the encapsulation layer TFE. In this case, the encapsulation layer TFE may be covered by the base insulating layer, and the first conductive layer ICL1 may be located on the base insulating layer. According to one or more embodiments of the present disclosure, the base insulating layer may contain an inorganic insulating material.

The first insulating layer IIL1 may cover the first conductive layer ICL1. The second conductive layer ICL2 may be located on the first insulating layer IIL1. Although a structure in which the input-sensing layer ISL may include the first and second conductive layers ICL1 and ICL2 is illustrated, the present disclosure is not limited thereto. For example, the input-sensing layer ISL may include only one of the first or second conductive layers ICL1 or ICL2.

The second insulating layer IIL2 may be located on the second conductive layer ICL2. The second insulating layer IIL2 may contain an organic insulating material. The second insulating layer IIL2 may serve to protect the first and second conductive layers ICL1 and ICL2 not only from moisture/oxygen, but also from foreign substances.

A color filter layer CFL may be located on the input-sensing layer ISL. The color filter layer CFL may be directly located on the second insulating layer IIL2. The color filter layer CFL may include a color filter CF, a dummy color filter DCF, a black matrix BM, and an overcoating layer OCL.

The color filter CF may include a first color filter, a second color filter, and a third color filter. The first color filter may have a first color, the second color filter may have a second color, and the third color filter may have a third color. According to one or more embodiments of the present disclosure, the first color may be red, the second color may be green, and the third color may be blue. The color filter illustrated in FIG. 6 may correspond to one of the first color filter, the second color filter, or the third color filter.

According to one or more embodiments of the present disclosure, the dummy color filter DCF may be located to correspond to the sensing region SA. The dummy color filter DCF may overlap the sensing region SA and the non-sensing region NSA. According to one or more other embodiments of the present disclosure, the dummy color filter DCF may have substantially the same color as one of the first, second, or third color filters. According to one or more other embodiments of the present disclosure, the dummy color filter DCF may have substantially the same green color as the second color filter. However, the present disclosure is not limited thereto. The color filter layer CFL may exclude the dummy color filter DCF.

The black matrix BM may be located to overlap the first and second conductive layers ICL1 and ICL2. According to one or more embodiments of the present disclosure, the black matrix BM may overlap the non-light-emitting region NPXA and the non-sensing region NSA. In one or more other embodiments, the black matrix BM may overlap first and third non-light-emitting regions. The black matrix BM may not overlap the light-emitting region PXA and the sensing region SA. According to one or more other embodiments of the present disclosure, a portion of the color filter CF may overlap the black matrix BM. In addition, a portion of the dummy color filter DCF may overlap the black matrix BM.

The overcoating layer OCL may contain an organic insulating material. The overcoating layer OCL may be provided with a thickness sufficient to remove a step difference between the color filter CF and the dummy color filter DCF. The material of the overcoating layer OCL may have a preset thickness and may flatten the upper surface of the color filter layer CFL. For example, the overcoating layer OCL may contain an acrylate-based organic material.

The window WM may be located on the color filter layer CFL.

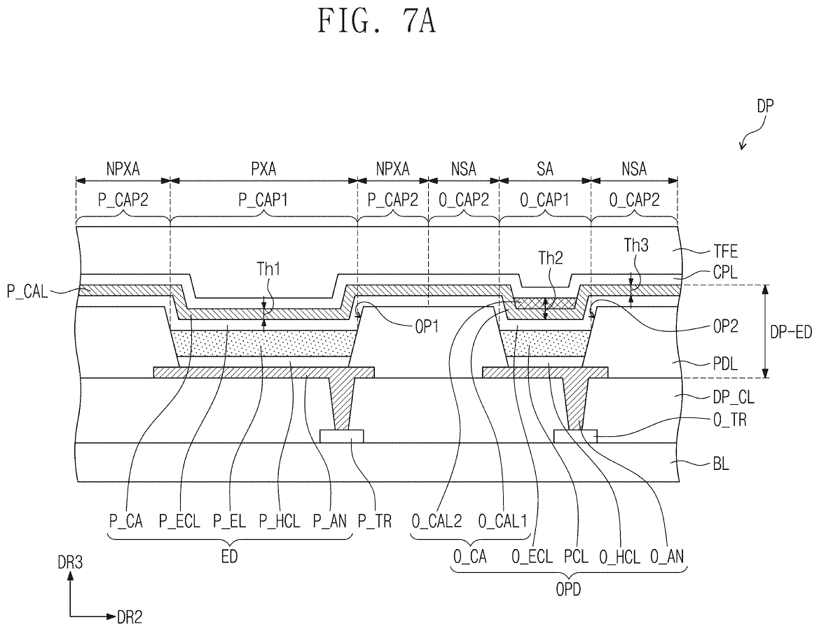

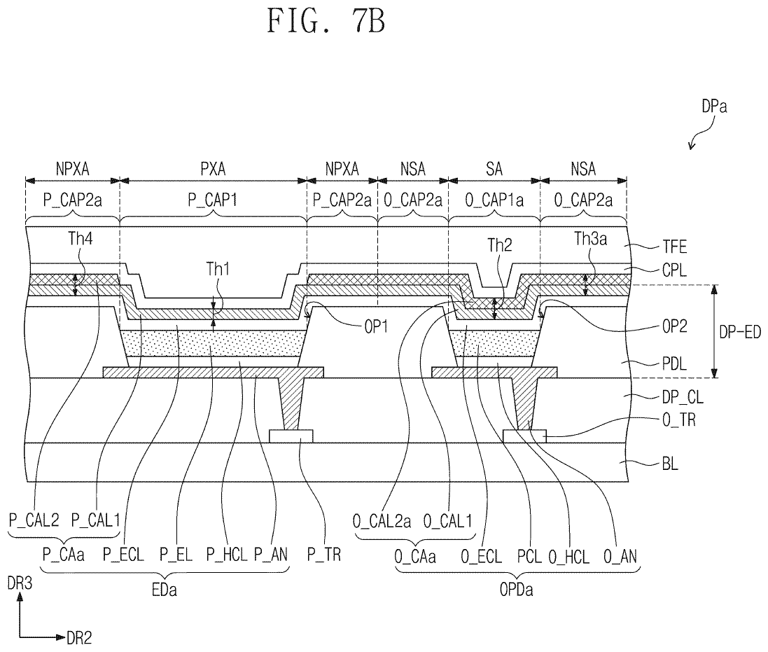

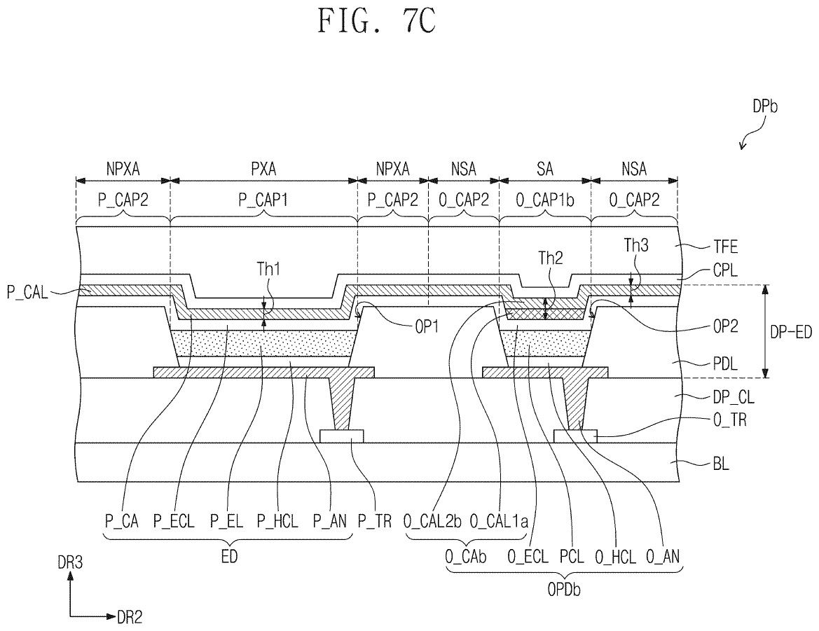

FIGS. 7A to 7C are enlarged cross-sectional views of display panels according to one or more embodiments of the present disclosure. FIG. 7A illustrates a circuit layer DP_CL, a light-emitting element ED, a light-receiving element OPD, an element-defining film PDL, a capping layer CPL, and an encapsulation layer TFE included in the display panel DP. Hereinafter, descriptions of substantially the same components as those described above will be omitted.

Referring to FIG. 7A, the element layer DP_ED may include a light-emitting element ED, a light-receiving element OPD, and an element-defining film PDL. The light-emitting element ED may include a pixel anode electrode P_AN, a pixel hole auxiliary layer P_HCL, a light-emitting layer P_EL, a pixel electron auxiliary layer P_ECL, and a pixel cathode electrode P_CA. Hereinafter, for the convenience of explanation, the pixel anode electrode P_AN will be referred to as a first pixel electrode, and the pixel cathode electrode P_CA will be referred to as a second pixel electrode. The light-emitting element ED may be electrically connected to the pixel transistor P_TR included in the circuit layer DP_CL.

A light-emitting region PXA overlapping the light-emitting layer P_EL and a non-light-emitting region NPXA surrounding the light-emitting region PXA may be defined in the element layer DP_ED. The light-emitting region PXA may be one of the green light-emitting region, the red light-emitting region, or the blue light-emitting region which are described above. In addition, the non-light-emitting region NPXA may be one of the green non-light-emitting region surrounding the green light-emitting region, the red non-light-emitting region surrounding the red light-emitting region, or the blue non-light-emitting region surrounding the blue light-emitting region which are described above.

The second pixel electrode P_CA may include a pixel electrode layer P_CAL. The pixel electrode layer P_CAL may be commonly located in a plurality of pixels PX (see FIG. 3). According to one or more embodiments of the present disclosure, the pixel electrode layer P_CAL may be located in the light-emitting region PXA and the non-light-emitting region NPXA. The pixel electrode layer P_CAL may have substantially the same configuration as the second pixel electrode P_CA. The pixel electrode layer P_CAL may include a transmissive electrode, a semi-transmissive electrode, or a reflective electrode. When the pixel electrode layer P_CAL is a transmissive electrode, the pixel electrode layer P_CAL may include transparent metal oxide, such as indium tin oxide (ITO), indium zinc oxide (IZO), zinc oxide (ZnO), and indium tin zinc oxide (ITZO). When the pixel electrode layer P_CAL is a semi-transmissive electrode or a reflective electrode, the pixel electrode layer P_CAL may contain Ag, Mg, Cu, Al, Pt, Pd, Au, Ni, Nd, Ir, Cr, Li, Ca, LiF/Ca, LiF/AI, Mo, Ti, Yb, W, or a compound or mixture thereof (e.g., a mixture of Ag and Mg).

The second pixel electrode P_CA may include a first pixel electrode portion P_CAP1 corresponding to the light-emitting region PXA, and a second pixel electrode portion P_CAP2 corresponding to the non-light-emitting region NPXA. The first pixel electrode portion P_CAP1 may overlap the light-emitting region PXA on a plane, and thus may overlap the light-emitting layer P_EL on a plane. The second pixel electrode portion P_CAP2 may overlap the non-light-emitting region NPXA.

According to one or more embodiments of the present disclosure, the light-receiving element OPD may include a sensing anode electrode O_AN, a sensing hole auxiliary layer O_HCL, a photoelectric conversion layer PCL, a sensing electron auxiliary layer O_ECL, and a sensing cathode electrode O_CA. Hereinafter, for the convenience of explanation, the sensing anode electrode O_AN will be referred to as a first sensing electrode, and the sensing cathode electrode O_CA will be referred to as a second sensing electrode.

A sensing region SA overlapping the photoelectric conversion layer PCL and a non-sensing region NSA surrounding the sensing region SA may be defined in the element layer DP_ED. For example, the sensing region SA may be defined by the second opening OP2 of the element-defining film PDL.

According to one or more embodiments of the present disclosure, the second sensing electrode O_CA may include a first sensing electrode layer O_CAL1 extending from the pixel electrode layer P_CAL, and a second sensing electrode layer O_CAL2 located on the first sensing electrode layer O_CAL1. The second sensing electrode layer O_CAL2 may be located on the first sensing electrode layer O_CAL1 in a portion overlapping the photoelectric conversion layer PCL so as to correspond to the sensing region SA. The second sensing electrode layer O_CAL2 may be formed in a process that is separate from that of the first sensing electrode layer O_CAL1. The second sensing electrode layer O_CAL2 may be formed by using a separate mask after the first sensing electrode layer O_CAL1 is formed. Details on this will be described later.

According to one or more embodiments of the present disclosure, the first sensing electrode layer O_CAL1 and the second sensing electrode layer O_CAL2 may contain substantially the same material as each other. For example, each of the first sensing electrode layer O_CAL1 and the second sensing electrode layer O_CAL2 may include a transmissive electrode, a semi-transmissive electrode, or a reflective electrode. When each of the first sensing electrode layer O_CAL1 and the second sensing electrode layer O_CAL2 is a transmissive electrode, each thereof may contain transparent metal oxide, such as indium tin oxide (ITO), indium zinc oxide (IZO), zinc oxide (ZnO), and indium tin zinc oxide (ITZO). When each of the first sensing electrode layer O_CAL1 and the second sensing electrode layer O_CAL2 is a semi-transmissive electrode or a reflective electrode, each thereof may include Ag, Mg, Cu, Al, Pt, Pd, Au, Ni, Nd, Ir, Cr, Li, Ca, LiF/Ca, LiF/AI, Mo, Ti, W or a compound or mixture thereof (e.g., a mixture of Ag and Mg). Without being limited thereto, however, the first sensing electrode layer O_CAL1 and the second sensing electrode layer O_CAL2 may contain different materials. The first sensing electrode layer O_CAL1 and the second sensing electrode layer O_CAL2 in direct contact with the first sensing electrode layer O_CAL1 may be electrically connected to each other.

The second sensing electrode O_CA may include a first sensing electrode portion O_CAP1 corresponding to the sensing region SA, and a second sensing electrode portion O_CAP2 corresponding to the non-sensing region NSA. The first sensing electrode portion O_CAP1 may overlap the photoelectric conversion layer PCL on a plane.

According to one or more embodiments of the present disclosure, a thickness Th1 of the second pixel electrode P_CA, and a thickness Th2 of the second sensing electrode O_CA, may be different from each other. For example, the thickness Th1 of the second pixel electrode P_CA, and the thickness Th2 of the first sensing electrode portion O_CAP1, may be different from each other. The thickness Th2 of the first sensing electrode portion O_CAP1 may be greater than the thickness Th1 of the second pixel electrode P_CA. The first sensing electrode portion O_CAP1 may include a portion of the first sensing electrode layer O_CAL1 and the second sensing electrode layer O_CAL2. The first sensing electrode layer O_CAL1 may have a structure extending from the pixel electrode layer P_CAL. The thickness of the first sensing electrode layer O_CAL1 and the thickness Th1 of the second pixel electrode P_CA may be substantially the same as each other. A difference between the thickness Th1 of the second pixel electrode P_CA and the thickness Th2 of the first sensing electrode portion O_CAP1 may be substantially the same as the thickness of the second sensing electrode layer O_CAL2.

According to one or more embodiments of the present disclosure, the thickness Th2 of the first sensing electrode portion O_CAP1 may be greater than a thickness Th3 of the second sensing electrode portion O_CAP2. Because the first sensing electrode portion O_CAP1 may include a portion of the first sensing electrode layer O_CAL1 and the second sensing electrode layer O_CAL2, and because the second sensing electrode portion O_CAP2 may include a portion of the first sensing electrode layer O_CAL1, the thickness Th2 of the first sensing electrode portion O_CAP1 may be greater than the thickness Th3 of the second sensing electrode portion O_CAP2 by as much as the thickness of the second sensing electrode layer O_CAL2. The thickness Th3 of the second sensing electrode portion O_CAP2 may be substantially equal to the thickness Th1 of the second pixel electrode P_CA. The first sensing electrode layer O_CAL1 may be formed through substantially the same process as the second pixel electrode P_CA, and may have a structure extending from the pixel electrode layer P_CAL. Because the second sensing electrode portion O_CAP2 is composed of a portion of the first sensing electrode layer O_CAL1, the thickness Th3 of the second sensing electrode portion O_CAP2 and the thickness Th1 of the second pixel electrode P_CA may be substantially the same as each other. In addition, because the first sensing electrode layer O_CAL1 may be formed through substantially the same process as the pixel electrode layer P_CAL, the pixel electrode layer P_CAL and the first sensing electrode layer O_CAL1 may have an integrated shape. The second sensing electrode O_CA may be electrically connected to the second pixel electrode P_CA through the first sensing electrode layer O_CAL1.

According to one or more embodiments of the present disclosure, the difference between the thickness Th1 of the second pixel electrode P_CA and the thickness Th2 of the second sensing electrode O_CA may be about 95 Å to about 145 Å. For example, the thickness of the second sensing electrode layer O_CAL2 may be about 95 Å to about 145 Å. Light emitted from the light-emitting layer P_EL may form a secondary resonance according to the wavelength of the light due to the thickness Th1 of the second pixel electrode P_CA, thereby enhancing light emission efficiency. In addition, light reflected by a user's fingerprint may form a secondary resonance according to the wavelength of the reflected light due to the thickness Th2 of the second sensing electrode O_CA overlapping the sensing region SA on a plane, thereby enhancing light reception efficiency. Because the second pixel electrode P_CA and the second sensing electrode O_CA are electrically connected to each other, the greater the thickness of the second sensing electrode O_CA is, the lower the overall resistance of the second pixel electrode P_CA and the second sensing electrode O_CA is. As the overall resistance of the second pixel electrode P_CA and the second sensing electrode O_CA is lowered, the heat generation phenomenon of the display panel DP may be improved, and display quality displayed by the pixels PX (see FIG. 3) may be improved. Because the display panel DP according to one or more embodiments of the present disclosure may include the second sensing electrode layer O_CAL2, the thickness Th2 of the second sensing electrode O_CA may be formed to be greater than the thickness Th1 of the second pixel electrode P_CA. Thus a reliable display panel DP may be provided.

Referring to FIG. 7B, a second pixel electrode P_CAa included in a light-emitting element EDa may include a first pixel electrode layer P_CAL1 located on the pixel electron auxiliary layer P_ECL, and a second pixel electrode layer P_CAL2 located on the first pixel electrode layer P_CAL1. The second pixel electrode layer P_CAL2 may be located on the first pixel electrode layer P_CAL1 so as to correspond to the non-light-emitting region NPXA. The second pixel electrode layer P_CAL2 may not overlap the light-emitting region PXA on a plane, and may overlap the non-light-emitting region NPXA on a plane. The second pixel electrode layer P_CAL2 may be formed in a process separate from that of the first pixel electrode layer P_CAL1. The second pixel electrode layer P_CAL2 may be formed by using a separate mask after the first pixel electrode layer P_CAL1 is formed. According to one or more embodiments of the present disclosure, the first pixel electrode layer P_CAL1 and the second pixel electrode layer P_CAL2 may contain substantially the same material as each other.

The second pixel electrode P_CAa included in the light-emitting element EDa may include a first pixel electrode portion P_CAP1 corresponding to the light-emitting region PXA, and a second pixel electrode portion P_CAP2a corresponding to the non-light-emitting region NPXA. The first pixel electrode portion P_CAP1 may overlap the light-emitting region PXA on a plane, and the second pixel electrode portion P_CAP2a may overlap the non-light-emitting region NPXA.

According to one or more embodiments of the present disclosure, a thickness Th1 of the first pixel electrode portion P_CAP1, and a thickness Th4 of the second pixel electrode portion P_CAP2a, may be different from each other. For example, the thickness Th4 of the second pixel electrode portion P_CAP2a may be greater than the thickness Th1 of the first pixel electrode portion P_CAP1. The first pixel electrode portion P_CAP1 may include a portion of the first pixel electrode layer P_CAL1. The second pixel electrode portion P_CAP2a may include a portion of the first pixel electrode layer P_CAL1 and the second pixel electrode layer P_CAL2. Accordingly, the difference between the thickness Th4 of the second pixel electrode portion P_CAP2a and the thickness Th1 of the first pixel electrode portion P_CAP1 may be substantially equal to the thickness of the second pixel electrode layer P_CAL2.

According to one or more embodiments of the present disclosure, a second sensing electrode O_CAa included in a light-receiving element OPDa may include a first sensing electrode layer O_CAL1 extending from the first pixel electrode layer P_CAL1 and a second sensing electrode layer O_CAL2a located on the first sensing electrode layer O_CAL1. For example, the second sensing electrode layer O_CAL2a may be located on the first sensing electrode layer O_CAL1 so as to correspond to the sensing region SA and the non-sensing region NSA. The second sensing electrode layer O_CAL2a may be formed in a process separate from that of the first sensing electrode layer O_CAL1. The second sensing electrode layer O_CAL2a may be formed by using a separate mask after the first sensing electrode layer O_CAL1 is formed. According to one or more other embodiments of the present disclosure, the first sensing electrode layer O_CAL1 and the second sensing electrode layer O_CAL2a may contain substantially the same material as each other.

The second sensing electrode O_CAa may include a first sensing electrode portion O_CAP1a corresponding to the sensing region SA, and a second sensing electrode portion O_CAP2a corresponding to the non-sensing region NSA. The first sensing electrode portion O_CAP1a and the second sensing electrode portion O_CAP2a may respectively overlap the sensing region SA and the non-sensing region NSA on a plane.

According to one or more embodiments of the present disclosure, a thickness Th2 of the first sensing electrode portion O_CAP1a, and a thickness Th3a of the second sensing electrode portion O_CAP2a, may be substantially the same as each other. Each of the first sensing electrode portion O_CAP1a and the second sensing electrode portion O_CAP2a may include a first sensing electrode layer O_CAL1 and a second sensing electrode layer O_CAL2a.

The thickness Th4 of the second pixel electrode portion P_CAP2a may be substantially equal to the thickness Th3a of the second sensing electrode portion O_CAP2a. The second pixel electrode layer P_CAL2 included in the second pixel electrode portion P_CAP2a may extend from the second sensing electrode layer O_CAL2a included in the second sensing electrode portion O_CAP2a. For example, the thickness Th4 of a second pixel electrode portion P_CPA2a, the thickness Th2 of the first sensing electrode portion O_CAP1a, and the thickness Th3a of the second sensing electrode portion O_CAP2a may be substantially the same as each other. The thickness Th1 of the first pixel electrode portion P_CAP1 including only the first pixel electrode layer P_CAL1 may be less than the thickness Th4 of the second pixel electrode portion P_CPA2a, less than the thickness Th2 of the first sensing electrode portion O_CAP1a, and less than the thickness Th3a of the second sensing electrode portion O_CAP2a. The difference between the thickness Th1 of the first pixel electrode portion P_CAP1 and each of the thickness Th4 of the second pixel electrode portion P_CPA2a, the thickness Th2 of the first sensing electrode portion O_CAP1a, and the thickness Th3a of the second sensing electrode portion O_CAP2a may be about 95 Å to about 145 Å.

Referring to FIG. 7C, a second sensing electrode O_CAb included in a light-receiving element OPDb may include a first sensing electrode layer O_CAL1a located on the sensing electron auxiliary layer O_ECL and a second sensing electrode layer O_CAL2b located on the first sensing electrode layer O_CAL1a and extending from the pixel electrode layer P_CAL. For example, the first sensing electrode layer O_CAL1a may be located on the sensing electron auxiliary layer O_ECL so as to correspond to the sensing region SA and overlap the photoelectric conversion layer PCL on a plane. The second sensing electrode layer O_CAL2b may be located on the first sensing electrode layer O_CAL1a and the sensing electron auxiliary layer O_ECL so as to correspond to the sensing region SA and the non-sensing region NSA. The second sensing electrode layer O_CAL2b may be formed in a process separate from that of the first sensing electrode layer O_CAL1a.

The second sensing electrode O_CAb may include a first sensing electrode portion O_CAP1b corresponding to the sensing region SA and a second sensing electrode portion O_CAP2 corresponding to the non-sensing region NSA. The first sensing electrode portion O_CAP1b may overlap the photoelectric conversion layer PCL on a plane.

When a display panel DPb illustrated in FIG. 7C is compared to the display panel DP illustrated in FIG. 7A, there is a difference between them in that the positions of the first sensing electrode layer O_CAL1a and the second sensing electrode layer O_CAL2b are changed with respect to each other. For example, the first sensing electrode layer O_CAL1a may be formed to overlap the photoelectric conversion layer PCL on a plane by using a separate mask, and then the second sensing electrode layer O_CAL2b may be formed as a common layer together with the pixel electrode layer P_CAL.

According to one or more embodiments of the present disclosure, the thickness Th1 of the second pixel electrode P_CA, and the thickness Th2 of the second sensing electrode O_CAb, may be different from each other. For example, the thickness Th1 of the second pixel electrode P_CA, and the thickness Th2 of the second sensing electrode O_CAb overlapping the sensing region SA on a plane, may be different from each other. The thickness Th2 of the second sensing electrode O_CAb overlapping the sensing region SA on a plane may be greater than the thickness Th1 of the second pixel electrode P_CA. The difference between the thickness Th1 of the second pixel electrode P_CA and the thickness Th2 of the second sensing electrode O_CAb may be substantially the same as the thickness of the first sensing electrode layer O_CAL1a. The thickness of the first sensing electrode layer O_CAL1a may be about 95 Å to about 145 Å.

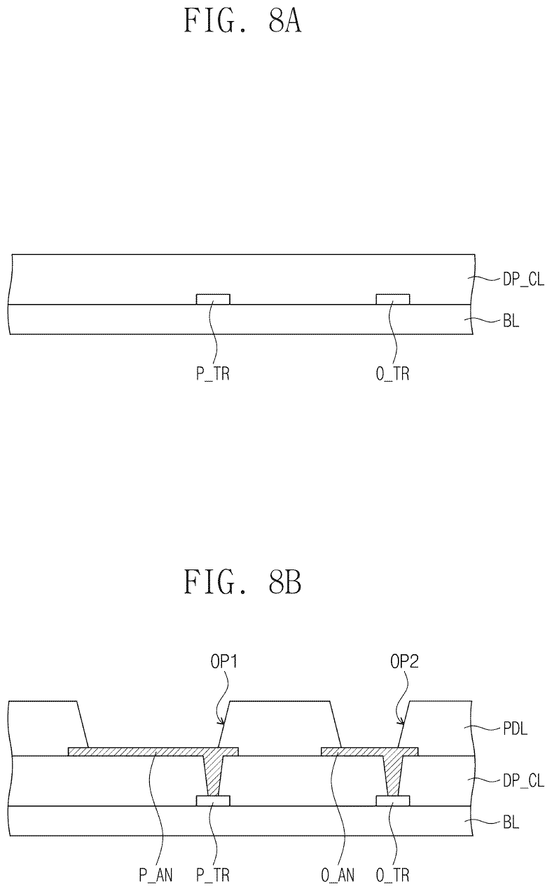

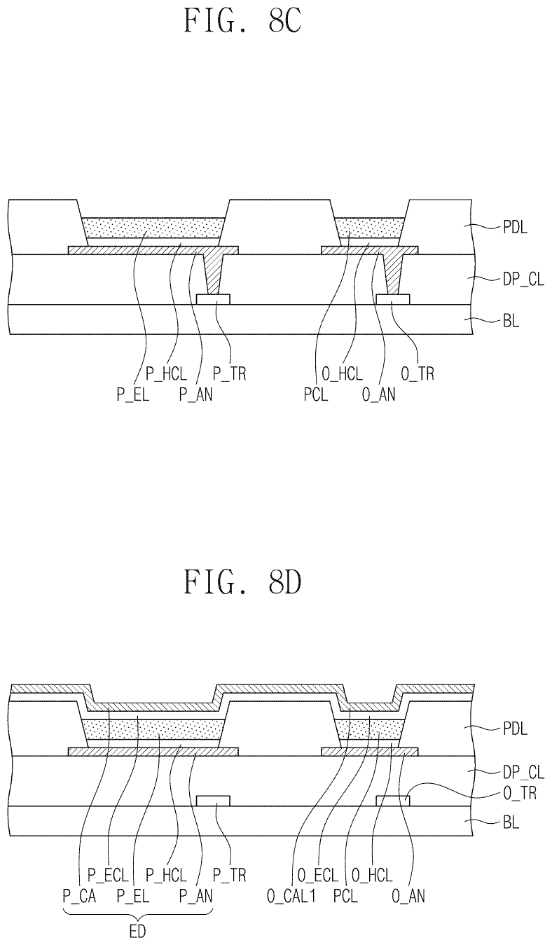

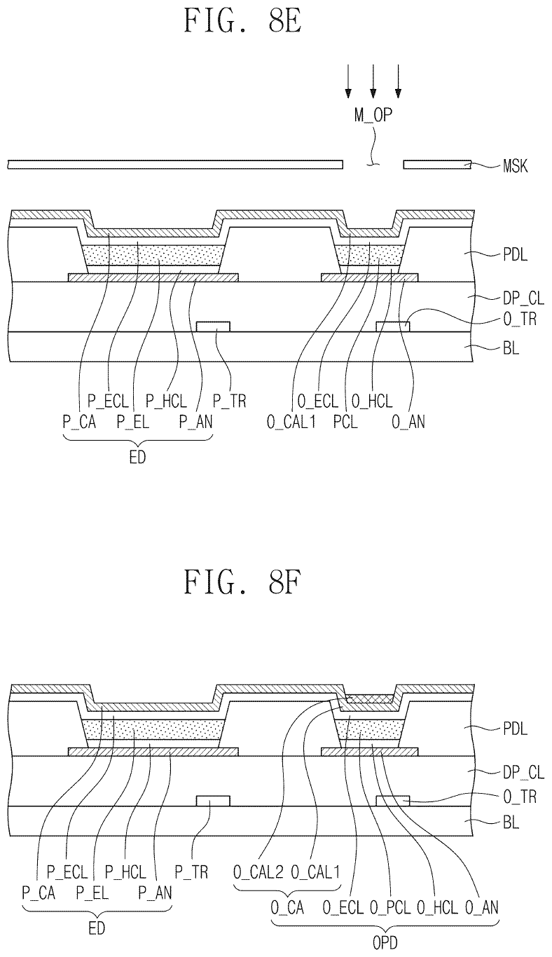

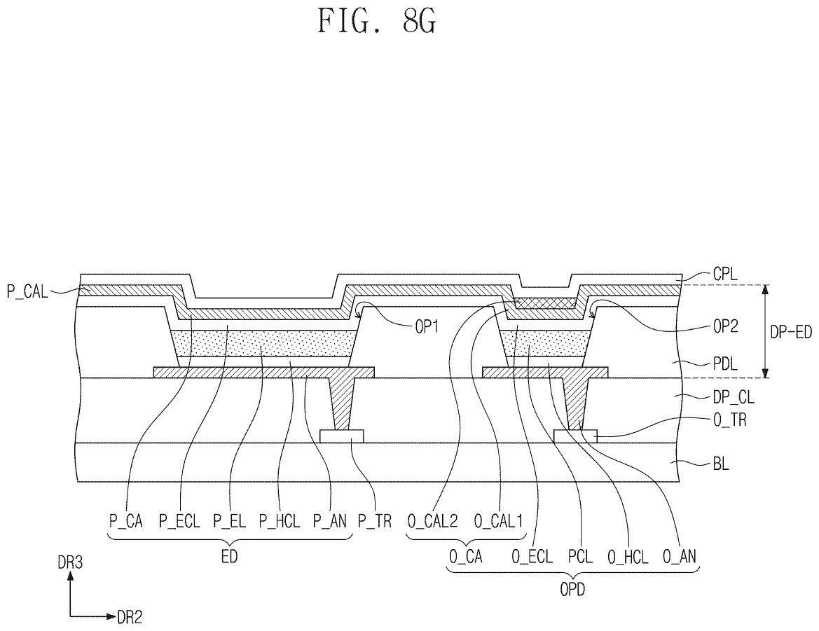

FIGS. 8A to 8G are cross-sectional views for describing a step of forming a portion of the display device according to one or more embodiments of the present disclosure.

Referring to FIG. 8A, a circuit layer DP_CL located on the base layer BL may be formed. The circuit layer DP_CL may include the pixel-driving circuit PDC (see FIG. 5) and the sensing-driving circuit SDC (see FIG. 5). FIG. 8A illustrates a pixel transistor P_TR which is a part of the pixel-driving circuit PDC (see FIG. 5), and a sensor transistor O_TR which is a part of the sensing-driving circuit SDC (see FIG. 5).

Referring to FIG. 8B, a first pixel electrode P_AN, a first sensing electrode O_AN, and an element-defining film PDL may be formed. The first pixel electrode P_AN may be electrically connected to the pixel transistor P_TR through a contact hole passing through an insulating layer included in the circuit layer DP_CL. The first sensing electrode O_AN may be electrically connected to the sensor transistor O_TR through a contact hole passing through an insulating layer included in the circuit layer DP_CL.

The element-defining film PDL may form an opening by patterning a preliminary insulating layer. For example, a first opening OP1 exposing a portion of the first pixel electrode P_AN, and a second opening OP2 exposing a portion of the first sensing electrode O_AN, may be formed. The element-defining film PDL may contain an organic insulating material. The element-defining film PDL may further contain a black material. In addition, the element-defining film PDL may further contain a black organic dye/pigment, such as carbon black or aniline black.

Referring to FIG. 8C, a pixel hole auxiliary layer P_HCL may be formed on the first pixel electrode P_AN, and a light-emitting layer P_EL may be formed on the pixel hole auxiliary layer P_HCL. In addition, a sensing hole auxiliary layer O_HCL may be formed on the first sensing electrode O_AN, and a photoelectric conversion layer PCL may be formed on the sensing hole auxiliary layer O_HCL.

The pixel hole auxiliary layer P_HCL and the sensing hole auxiliary layer O_HCL may be formed in common. For example, the pixel hole auxiliary layer P_HCL and the sensing hole auxiliary layer O_HCL may be located as a common layer(s) on the first pixel electrode P_AN, the first sensing electrode O_AN, and the element-defining film PDL by commonly using a physical vapor deposition method. Hereinafter, the pixel hole auxiliary layer P_HCL and the sensing hole auxiliary layer O_HCL may be formed on the common layers by patterning with the use of a fine metal mask in a region overlapping the first opening OP1 and the second opening OP2.

Hereinafter, by using substantially the same fine metal mask, the light-emitting layer P_EL may be formed so as to correspond to the first opening OP1 (see FIG. 8B), and the photoelectric conversion layer PCL may be formed so as to correspond to the second opening OP2 (see FIG. 8B). In one or more embodiments, a patterned light-emitting layer P_EL is illustrated as an example, but the present disclosure is not limited thereto. A common light-emitting layer may be commonly located in a plurality of pixels PX (see FIG. 3). In this case, the common light-emitting layer may generate white light or blue light.

Referring to FIG. 8D, a common layer may be formed on the light-emitting layer P_EL, the photoelectric conversion layer PCL, and the element-defining film PDL. The common layer may be commonly located in a plurality of pixels PX (see FIG. 3) and a plurality of sensors FX (see FIG. 3). For example, the common layer may include a pixel electron auxiliary layer P_ECL corresponding to the first opening OP1 (see FIG. 8B), a second pixel electrode P_CA, a sensing electron auxiliary layer O_ECL corresponding to the second opening OP2 (see FIG. 8B), and a first sensing electrode layer O_CAL1 included in the second sensing electrode O_CA (see FIG. 6). The sensing electron auxiliary layer O_ECL may extend from the pixel electron auxiliary layer P_ECL, and the first sensing electrode layer O_CAL1 may extend from the second pixel electrode P_CA. For example, the sensing electron auxiliary layer O_ECL and the pixel electron auxiliary layer P_ECL may be formed in common in substantially the same process as each other, and the first sensing electrode layer O_CAL1 and the second pixel electrode P_CA may be formed in common in substantially the same process as each other. In one or more embodiments, the second pixel electrode P_CA may include a first pixel electrode layer P_CAL1 (see FIG. 7B) and a second pixel electrode layer P_CAL2 (see FIG. 7B) located on the first pixel electrode layer P_CAL1. In this case, the first pixel electrode layer P_CAL1 (see FIG. 7B) and the first sensing electrode layer O_CAL1 may be integrally formed in substantially the same process as each other.

Referring to FIGS. 8E and 8F, a second sensing electrode layer O_CAL2 may be formed on the first sensing electrode layer O_CAL1 so as to provide a second sensing electrode O_CA.

After the first sensing electrode layer O_CAL1 and the second pixel electrode P_CA are formed, the second sensing electrode layer O_CAL2 may be formed on the first sensing electrode layer O_CAL1. For example, the second sensing electrode layer O_CAL2 may be formed on the first sensing electrode layer O_CAL1 in a region overlapping the photoelectric conversion layer PCL.

The second sensing electrode layer O_CAL2 may be formed by using a mask MSK located on the first sensing electrode layer O_CAL1. According to one or more embodiments of the present disclosure, the second sensing electrode layer O_CAL2 may be formed through deposition so as to correspond to an opening M_OP of the mask MSK. Without being limited thereto, however, a preliminary second sensing electrode layer may be formed on the second pixel electrode P_CA and the first sensing electrode layer O_CAL1, and by arranging a mask in a region overlapping the photoelectric conversion layer PCL, the second sensing electrode layer O_CAL2 may be formed through a process of patterning the entire region excluding the region overlapping the photoelectric conversion layer PCL. The mask MSK may include a fine metal mask.

According to one or more embodiments of the present disclosure, the thickness of the second pixel electrode P_CA and the thickness of the second sensing electrode O_CA may be different from each other. For example, the thickness of the second pixel electrode P_CA and the thickness of the second sensing electrode O_CA overlapping the photoelectric conversion layer PCL on a plane may be different from each other. The thickness of the second sensing electrode O_CA overlapping the photoelectric conversion layer PCL on a plane may be greater than the thickness of the second pixel electrode P_CA. The thickness of the first sensing electrode layer O_CAL1 and the thickness of the second pixel electrode P_CA may be substantially the same as each other. Accordingly, the difference between the thickness of the second sensing electrode O_CA overlapping the photoelectric conversion layer PCL on a plane and the thickness of the second pixel electrode P_CA may be substantially equal to the thickness of the second sensing electrode layer O_CAL2.

The thickness of the second sensing electrode layer O_CAL2 may be about 95 Å to about 145 Å. The first sensing electrode layer O_CAL1 and the second sensing electrode layer O_CAL2 may be electrically connected to each other. The second pixel electrode P_CA and the first sensing electrode layer O_CAL1 may be electrically connected to each other. Accordingly, the second pixel electrode P_CA and the second sensing electrode O_CA may be electrically connected to each other. The greater the thickness of the second sensing electrode O_CA is, then the lower the overall resistance of the second pixel electrode P_CA and the second sensing electrode O_CA is. As the overall resistance of the second pixel electrode P_CA and the second sensing electrode O_CA is lowered, the heat generation phenomenon of the display panel DP (see FIG. 8G) may be improved, and display quality displayed by the pixels PX (see FIG. 3) may be improved. As the display panel DP according to one or more embodiments of the present disclosure may include the second sensing electrode layer O_CAL2, a reliable display panel DP (see FIG. 8G) may be provided.

In one or more embodiments, after the first sensing electrode layer O_CAL1a is formed to overlap the photoelectric conversion layer PCL on a plane, the second sensing electrode layer O_CAL2b may be formed as a common layer together with the pixel electrode layer P_CAL.

Referring to FIG. 8G, a capping layer CPL may be located on the second pixel electrode P_CA and the second sensing electrode O_CA. The capping layer CPL may include multiple layers or a single layer. In one or more embodiments of the present disclosure, the capping layer CPL may be an organic layer or an inorganic layer.

As the display panel according to one or more embodiments of the present disclosure may include the second sensing electrode layer located on the first sensing electrode layer, the thickness of the second sensing electrode may be formed to be greater than the thickness of the second pixel electrode. Therefore the resistance of the second sensing electrode and the second pixel electrode may be reduced so that a reliable display panel can be provided.

Although the above has been described with reference to one or more embodiments of the present disclosure, those skilled in the art or those of ordinary skill in the art will understand that various modifications and changes can be made to the present disclosure within the scope that does not depart from the spirit and technical field of the present disclosure described in the claims to be described later, with functional equivalents thereof to be included therein.

Accordingly, the technical scope of the present disclosure should not be limited to the content described in the detailed description of the specification, but should be determined by the claims described hereinafter, with functional equivalents thereof to be included therein.

What is claimed is:

1. A display device comprising:
a base layer;
a circuit layer above the base layer; and
an element layer above the circuit layer, and comprising:
a light-emitting element comprising a first pixel electrode electrically connected to the circuit layer, a light-emitting layer above the first pixel electrode, and a second pixel electrode above the light-emitting layer; and
a light-receiving element adjacent to the light-emitting element, and comprising a first sensing electrode electrically connected to the circuit layer, a photoelectric conversion layer above the first sensing electrode, and a second sensing electrode above the photoelectric conversion layer and having a thickness that is different than a thickness of the second pixel electrode.

2. The display device of claim 1, wherein the thickness of the second sensing electrode is greater than the thickness of the second pixel electrode.

3. The display device of claim 2, wherein the second pixel electrode comprises a pixel electrode layer, and
wherein the second sensing electrode comprises a first sensing electrode layer extending from the pixel electrode layer, and a second sensing electrode layer above the first sensing electrode layer.

4. The display device of claim 2, wherein the second pixel electrode comprises a pixel electrode layer, and
wherein the second sensing electrode comprises a first sensing electrode layer, and a second sensing electrode layer above first sensing electrode layer and extending from the pixel electrode layer.

5. The display device of claim 1, wherein the element layer defines a light-emitting region overlapping the light-emitting layer, and a non-light-emitting region surrounding the light-emitting region in a plan view.

6. The display device of claim 5, wherein the second pixel electrode comprises a first pixel electrode portion corresponding to the light-emitting region, and a second pixel electrode portion corresponding to the non-light-emitting region.

7. The display device of claim 6, wherein a thickness of the first pixel electrode portion is different from a thickness of the second pixel electrode portion.

8. The display device of claim 7, wherein the thickness of the second pixel electrode portion is greater than the thickness of the first pixel electrode portion.

9. The display device of claim 7, wherein the thickness of the second pixel electrode portion is substantially equal to the thickness of the second sensing electrode.

10. The display device of claim 1, wherein the element layer defines a sensing region overlapping the photoelectric conversion layer and a non-sensing region surrounding the sensing region.

11. The display device of claim 10, wherein the second sensing electrode comprises a first sensing electrode portion corresponding to the sensing region, and a second sensing electrode portion corresponding to the non-sensing region.

12. The display device of claim 11, wherein a thickness of the first sensing electrode portion is different from a thickness of the second sensing electrode portion.

13. The display device of claim 12, wherein the thickness of the first sensing electrode portion is greater than the thickness of the second sensing electrode portion.

14. The display device of claim 12, wherein the thickness of the second sensing electrode portion is substantially equal to the thickness of the second pixel electrode.

15. The display device of claim 1, wherein the second pixel electrode and the second sensing electrode are electrically connected to each other.

16. The display device of claim 1, wherein the circuit layer comprises a pixel-driving circuit electrically connected to the light-emitting element for controlling an operation of the light-emitting element, and a sensing-driving circuit electrically connected to the light-receiving element for controlling the operation of the light-receiving element.

17. The display device of claim 16, comprising:
a black matrix above the element layer, and comprising openings; and
a color filter above the element layer, and overlapping the openings.

18. A method for manufacturing a display device, the method comprising:
placing a circuit layer above a base layer; and
placing an element layer comprising a light-emitting element and a light-receiving element above the circuit layer, the placing of the element layer comprising:
forming a first pixel electrode of the light-emitting element and a first sensing electrode of the light-receiving element above the circuit layer;
forming a light-emitting layer on the first pixel electrode and a photoelectric conversion layer above the first sensing electrode; and
forming a second pixel electrode above the light-emitting layer and a second sensing electrode on the photoelectric conversion layer, a thickness of the second sensing electrode being greater than a thickness of the second pixel electrode.

19. The method of claim 18, wherein the forming of the second pixel electrode and the second sensing electrode comprises:
forming a first pixel electrode layer above the light-emitting layer, and a first sensing electrode layer above the photoelectric conversion layer; and
forming a second sensing electrode layer above the first sensing electrode layer.

20. The method of claim 19, wherein the first pixel electrode layer and the first sensing electrode layer are integrally formed with each other.
